(19) United States
(12) Patent Application Publication
(10) Pub. No.: US 2010/0123883 A1
(43) Pub. Date: May 20, 2010

(54) PROJECTION OPTICAL SYSTEM, EXPOSURE APPARATUS, AND DEVICE MANUFACTURING METHOD

(75) Inventor: Yasuhiro Ohmura, Kounosu-shi (JP)

Correspondence Address: KLARQUIST SPARKMAN, LLP, 121 SW SALMON STREET, SUITE 1600, PORTLAND, OR, 97204, US

(73) Assignee: Nikon Corporation

(21) Appl. No.: 12/562,043

(22) Filed: Sep. 17, 2009

Related U.S. Application Data
(60) Provisional application No. 61/193,304, filed on Nov. 17, 2008.

(51) Int. Cl. G03F 7/20; G02B 17/08; G03B 27/70; G03B 27/54

(52) U.S. Cl. 355/51; 359/434; 359/365; 355/66; 355/77; 355/67

(57) ABSTRACT

An object is to provide a projection optical system, for example, capable of improving the throughput of scanning exposure in application to scanning exposure apparatus. A projection optical system for forming an image of a first surface and an image of a second surface on a third surface comprises a first imaging optical system, a second imaging optical system, a third imaging optical system, a fourth imaging optical system, a fifth imaging optical system, a sixth imaging optical system, a seventh imaging optical system, a first folding member disposed between the third imaging optical system and the seventh imaging optical system, and a second folding member disposed between the sixth imaging optical system and the seventh imaging optical system.

### CROSS-REFERENCE TO RELATED APPLICATIONS

This application is based upon and claims the benefit of priorities from U.S. Provisional Application No. 61/193,304, filed on Nov. 17, 2008, the entire contents of which are incorporated herein by reference.

### BACKGROUND OF THE INVENTION

1. Field

An embodiment of the present invention relates to a projection optical system, exposure apparatus, and device manufacturing method.

2. Description of the Related Art

In the photolithography process for manufacturing the semiconductor devices and others, a scanning exposure apparatus is used for performing scanning exposure of a pattern of a mask (or reticle) on a photosensitive substrate (a wafer coated with a photoresist, or the like) through a projection optical system. An ordinary scanning exposure apparatus is configured to alternately repeat an operation of scanning exposure in one shot area and an operation of step movement of the photosensitive substrate to a next shot area (e.g., U.S. Reissued Pat. No. 37,391).

### SUMMARY

An embodiment of the present invention provides a projection optical system, for example, capable of improving the throughput of the scanning exposure in application to the scanning exposure apparatus. An embodiment of the present invention provides an exposure apparatus capable of improving the throughput of scanning exposure, using the projection optical system of the embodiment of the present invention.

For purposes of summarizing the invention, certain aspects, advantages, and novel features of the invention have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessary achieving other advantages as may be taught or suggested herein.

A first embodiment of the present invention provides a projection optical system for forming an image of a first surface and an image of a second surface on a third surface, comprising:

a first imaging optical system disposed in an optical path between the first surface and a first conjugate point optically conjugate with a point which is on the first surface and at which an optical axis intersects with the first surface;

a second imaging optical system disposed in an optical path between the first conjugate point and a second conjugate point optically conjugate with the point which is on the first surface and at which an optical axis intersects with the first surface;

a third imaging optical system disposed in an optical path between the second conjugate point and a third conjugate point optically conjugate with the point which is on the first surface and at which an optical axis intersects with the first surface;

a fourth imaging optical system disposed in an optical path between the second surface and a fourth conjugate point optically conjugate with a point which is on the second surface and at which an optical axis intersects with the second surface;

a fifth imaging optical system disposed in an optical path between the fourth conjugate point and a fifth conjugate point optically conjugate with the point which is on the second surface and at which an optical axis intersects with the second surface;

a sixth imaging optical system disposed in an optical path between the fifth conjugate point and a sixth conjugate point optically conjugate with the point which is on the second surface and at which an optical axis intersects with the second surface;

a seventh imaging optical system disposed in an optical path between the third surface and the third and sixth conjugate points;

a first folding member disposed in an optical path between a surface nearest to the third surface in the third imaging optical system and a surface nearest to the first surface in the seventh imaging optical system and configured to guide light from the third imaging optical system to the seventh imaging optical system; and

a second folding member disposed in an optical path between a surface nearest to the third surface in the sixth imaging optical system and a surface nearest to the second surface in the seventh imaging optical system and configured to guide light from the sixth imaging optical system to the seventh imaging optical system,

wherein every optical element with a power in the seventh imaging optical system is a refracting optical element.

A second embodiment of the present invention provides a projection optical system for forming an image of a first surface and an image of a second surface on a third surface, which is one to be used in an exposure apparatus for transferring a predetermined pattern set on at least one of the first surface and the second surface, to a photosensitive substrate set on the third surface, the projection optical system comprising:

a first optical unit which guides light from the first surface to a path combining device;

a second optical unit which guides light from the second surface to the path combining device; and

a third optical unit which forms the image of the first surface on the third surface, based on the light from the first optical unit having traveled via the path combining device, and which forms the image of the second surface on the third surface, based on the light from the second optical unit having traveled via the path combining device,

wherein the first surface, the second surface, and the third surface extend horizontally in a space below the projection optical system, and

wherein the third surface is located below the first surface and the second surface.

A third embodiment of the present invention provides an exposure apparatus comprising the projection optical system of the first embodiment or the second embodiment for, based on light from a predetermined pattern set on at least one of the first surface and the second surface, projecting the predetermined pattern onto a photosensitive substrate set on the third surface.

A fourth embodiment of the present invention provides an exposure apparatus comprising a projection optical system for forming an image of a first surface and an image of a second surface on a third surface, which is for transferring a predetermined pattern set on at least one of the first surface and the second surface, to a photosensitive substrate set on the third surface, the exposure apparatus comprising:

a first illumination unit which is located below the first surface and which provides a first illumination light with the first surface,

a second illumination unit which is located below the second surface and which provides a second illumination light with the second surface,

wherein the first surface, the second surface, and the third surface extend horizontally in a space below the projection optical system.

A fifth embodiment of the present invention provides a device manufacturing method comprising:

exposing of the predetermined pattern on the photosensitive substrate, using the exposure apparatus of the third or the fourth embodiment;

developing the photosensitive substrate on which the predetermined pattern has been transferred, to form a mask layer in a shape corresponding to the predetermined pattern on a surface of the photosensitive substrate; and

processing the surface of the photosensitive substrate through the mask layer.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is a drawing schematically showing a configuration of an exposure apparatus according to an embodiment of the present invention.

FIG. 2 is a drawing showing rectangular illumination regions formed on a first mask and on a second mask, respectively.

FIG. 3 is a drawing showing a pattern image of the first mask and a pattern image of the second mask formed through a projection optical system.

FIG. 4 is a drawing showing a positional relation among rectangular still exposure regions formed on a wafer, and a reference optical axis in the embodiment.

FIG. 5 is a drawing schematically showing a configuration between a boundary lens and a wafer in the embodiment.

FIG. 6 is a drawing showing a lens configuration of a projection optical system according to the first example of the embodiment.

FIG. 7 is a drawing showing transverse aberrations in the projection optical system of the first example.

FIG. 8 is a drawing showing a lens configuration of a projection optical system according to the second example of the embodiment.

FIG. 9 is a drawing showing transverse aberrations in the projection optical system of the second example.

FIG. 10 is a drawing showing a lens configuration of a projection optical system according to the third example of the embodiment.

FIG. 11 is a drawing showing transverse aberrations in the projection optical system of the third example.

FIG. 12 is a drawing showing a lens configuration of a projection optical system according to a modification example of the third example.

FIG. 13 is a drawing for explaining an exposure sequence of continuously carrying out scanning exposures in a plurality of shot areas aligned in a scanning direction.

FIG. 14 is a flowchart of a method for manufacturing semiconductor devices.

FIG. 15 is a flowchart of a method for manufacturing a liquid crystal display device.

### DESCRIPTION

A projection optical system according to an embodiment of the present invention comprises a first optical unit having a first imaging optical system, a second imaging optical system, and a third imaging optical system, a second optical unit having a fourth imaging optical system, a fifth imaging optical system, and a sixth imaging optical system, and a third optical unit having a seventh imaging optical system, and is configured to form an image of a first surface (first object plane) and an image of a second surface (second object plane) on a third surface (image plane). The first imaging optical system is disposed in an optical path between the first surface and a first conjugate point optically conjugate with a point on an optical axis, the second imaging optical system is disposed in an optical path between the first conjugate point and a second conjugate point optically conjugate with the point on the optical axis, and the third imaging optical system is disposed in an optical path between the second conjugate point and a third conjugate point optically conjugate with the point on the optical axis.

The fourth imaging optical system is disposed in an optical path between the second surface and a fourth conjugate point optically conjugate with a point on an optical axis, the fifth imaging optical system is disposed in an optical path between the fourth conjugate point and a fifth conjugate point optically conjugate with the point on the optical axis, and the sixth imaging optical system is disposed in an optical path between the fifth conjugate point and a sixth conjugate point optically conjugate with the point on the optical axis. The seventh imaging optical system is disposed in an optical path between the third surface and the third and sixth conjugate points.

The projection optical system of the embodiment of the present invention comprises a first folding member which guides light from the third imaging optical system to the seventh imaging optical system, and a second folding member which guides light from the sixth imaging optical system to the seventh imaging optical system, and every optical element with a power in the seventh imaging optical system is a refracting optical element. Namely, the seventh imaging optical system is a refractive optic system. The first folding member is disposed in an optical path between the third imaging optical system and the seventh imaging optical system and the second folding member is disposed in an optical path between the sixth imaging optical system and the seventh imaging optical system.

In the projection optical system of the embodiment of the present invention as constructed in this configuration, the first imaging optical system forms a first intermediate image at or near the first conjugate point, based on light from the first surface, the second imaging optical system forms a second intermediate image at or near the second conjugate point, based on light from the first intermediate image, the third imaging optical system forms a third intermediate image at or near the third conjugate point, based on light from the second intermediate image, and the seventh imaging optical system forms a first final image on the third surface, based on light from the third intermediate image.

On the other hand, the fourth imaging optical system forms a fourth intermediate image at or near the fourth conjugate point, based on light from the second surface, the fifth imaging optical system forms a fifth intermediate image at or near the fifth conjugate point, based on light from the fourth intermediate image, the sixth imaging optical system forms a sixth intermediate image at or near the sixth conjugate point, based on light from the fifth intermediate image, and the seventh imaging optical system forms a second final image at a position in parallel with the first final image on the third surface, based on light from the sixth intermediate image.

Since the projection optical system of the embodiment of the present invention adopts the double-headed basic configuration of the four-fold imaging type as described above, it is able to ensure required levels of image-side numerical aperture and effective image region and, for example, to form images of patterns on two object planes spaced from each other, in parallel in a predetermined region on the image plane. As a consequence, for example, when the projection optical system of the embodiment of the present invention is applied to the scanning exposure apparatus, it is able to form images of patterns on two masks spaced from each other, in parallel in an effective image region of the projection optical system and to print two different patterns as superimposed in one shot area on a photosensitive substrate by a single scan operation.

When the exposure apparatus is configured to repeat an operation of scanning exposure of a pattern of a first mask in a first shot area, an operation of scanning exposure of a pattern of a second mask in a second shot area adjacent in a scanning movement direction to the first shot area, and an operation of scanning exposure of the pattern of the first mask in a third shot area adjacent in the scanning movement direction to the second shot area by a required number of times, it is able to continuously perform scanning exposure in a plurality of shot areas aligned in the scanning direction, by simply moving the photosensitive substrate along the scanning direction, without need for performing two-dimensional step movement of the photosensitive substrate. Namely, when the projection optical system of the embodiment of the present invention is applied to the scanning exposure apparatus, the throughput of scanning exposure is drastically improved.

When the projection optical system of the embodiment of the present invention is applied, for example, to a semiconductor exposure apparatus, it can be configured as an optical system having a reduction magnification. In the projection optical system of the embodiment of the present invention, the first imaging optical system and third imaging optical system, and the fourth imaging optical system and sixth imaging optical system can also be configured as refractive systems like the seventh imaging optical system. In this case, since refracting optical elements can be manufactured with stable surface accuracy, it is feasible to improve the stability of the optical systems and to reduce the manufacture cost of the optical systems.

In the projection optical system of the embodiment of the present invention, the first optical unit being an optical system from the first surface to the first folding member, and the second optical unit being an optical system from the second surface to the second folding member may have the same configuration. This allows the projection optical system to have a configuration symmetrical with respect to the optical axis of the seventh imaging optical system, whereby it becomes feasible to improve the stability of the optical system, to simplify the configuration of the optical system, and to reduce the manufacture cost of the optical system.

In the projection optical system of the embodiment of the present invention, when each of the second imaging optical system and the fifth imaging optical system adopts a configuration with a concave reflecting mirror, the projection optical system is corrected well for chromatic aberration while securing a large image-side numerical aperture. When each of the second imaging optical system and the fifth imaging optical system adopts a configuration with a negative lens, more specifically, when the negative lens is disposed near the concave reflecting mirror, it is feasible to achieve a good compensation for the Petzval sum.

In the projection optical system of the embodiment of the present invention, a third folding member can be disposed in an optical path between the first surface and the first folding member and a fourth folding member can be disposed in an optical path between the second surface and the second folding member. Specifically, the third folding member can be disposed in an optical path between the second imaging optical system and the third imaging optical system and the fourth folding member can be disposed in an optical path between the fifth imaging optical system and the sixth imaging optical system. In this case, where the third folding member is disposed near the second conjugate point and where the fourth folding member is disposed near the fifth conjugate point, it becomes easier to separate a going beam from a returning beam relative to the concave reflecting mirror in each of the second imaging optical system and the fifth imaging optical system.

Alternatively, the third folding member can be disposed in an optical path between the first imaging optical system and the second imaging optical system and the fourth folding member can be disposed in an optical path between the fourth imaging optical system and the fifth imaging optical system. In this case, where the third folding member is disposed near the first conjugate point and where the fourth folding member is disposed near the fourth conjugate point, it also becomes easier to separate the going beam from the returning beam relative to the concave reflecting mirror in each of the second imaging optical system and the fifth imaging optical system. As a consequence, there is no need for setting a large space between a first effective field region and the optical axis on the first surface and a large space between a second effective field region and the optical axis on the second surface, whereby a maximum image height is reduced on the third surface and, in turn, it becomes easier to achieve reduction in the size of the optical system.

In the projection optical system of the embodiment of the present invention, the first folding member can be disposed near the third conjugate point and the second folding member can be disposed near the sixth conjugate point. In this case, it is feasible to make small a space between the optical axis and a first effective image region formed on the third surface corresponding to the first effective field region on the first surface and make small a space between the optical axis and a second effective image region formed on the third surface corresponding to the second effective field region on the second surface. As a consequence, a maximum image height is reduced on the third surface and, in turn, it becomes easier to achieve reduction in the size of the optical system.

The projection optical system of the embodiment of the present invention may have a first effective field region not including the optical axis of the first imaging optical system on the first surface, and a second effective field region not including the optical axis of the fourth imaging optical system on the second surface, and satisfies Condition Expressions (1) and (2) below. In Condition Expressions (1) and (2), LO1 is a distance between the optical axis of the seventh imaging optical system and a first effective image region formed on the third surface corresponding to the first effective field region, and LO2 is a distance between the optical axis of the seventh imaging optical system and a second effective image region formed on the third surface corresponding to the second effective field region. Furthermore, B is a maximum image height on the third surface.

0.05<LO1/B<0.4 (1)

0.05<LO2/B<0.4 (2)

When the ratios are smaller than the lower limit of Condition Expressions (1) and (2), it will result in excessively limiting an amount of aberration occurring at each conjugate point for path separation of the going and returning paths relative to the concave reflecting mirror. When the ratios are larger than the upper limit of Condition Expressions (1) and (2), it will result in increase in the scale of the projection optical system and increase in scan distance necessary for scanning exposure of two mask patterns in one shot area by a single scan operation, and thereby cause reduction in throughput. For better achieving the effects of the embodiment of the present invention, the lower limit of Condition Expressions (1) and (2) can be set to 0.10. For better achieving the effects of the embodiment of the present invention, the upper limit of Condition Expressions (1) and (2) can be set to 0.32.

When the projection optical system of the embodiment of the present invention is arranged so that a normal to a reflecting surface of each folding member makes 45° relative to the optical axis, the optical axes of the respective imaging optical systems can be made parallel or perpendicular to each other and it is eventually feasible to facilitate arrangement of the optical systems. In other words, it is possible to adopt a configuration wherein a reflecting surface of the first folding member and a reflecting surface of the second folding member are arranged at 45° relative to the optical axis of the seventh imaging optical system, wherein a reflecting surface of the third folding member is arranged at 45° relative to the optical axis of the first imaging optical system, and wherein a reflecting surface of the fourth folding member is arranged at 45° relative to the optical axis of the fourth imaging optical system.

In the projection optical system of the embodiment of the present invention, the reflecting surface of the first folding member and the reflecting surface of the third folding member may be arranged in parallel with each other and the reflecting surface of the second folding member and the reflecting surface of the fourth folding member are arranged in parallel with each other. In this configuration, there is variation in angles of incidence of rays incident to the reflecting surfaces of the respective folding members arranged near the conjugate points, but, with focus on one ray, the ray incident at an incidence angle of 45°+α to the reflecting surface of the third folding member or the fourth folding member is incident at an incidence angle of 45°−α′ to the reflecting surface of the first folding member or the second folding member; therefore, an average of the incidence angles in the two reflections becomes close to 45°.

For example, there are only limited film materials with a small absorption loss of light in reflection of ArF excimer laser light used as exposure light and it is also difficult to increase the number of film layers. For this reason, the reflectance and phase modulation of a reflecting surface tend to have a difference depending upon angles of incidence of light (incidence angle characteristics). However, when the projection optical system adopts the arrangement wherein the pair of reflecting surfaces are parallel to each other as described above, it is feasible to average the incidence angles in two reflections and to suppress influence of the incidence angle characteristics of the reflecting surfaces, thereby maintaining good imaging performance. When an imaging magnification of the optical system between the third folding member and the first folding member and an imaging magnification of the optical system between the fourth folding member and the second folding member are set closer to unit magnification (1:1 imaging), the angles α and α′ become approximately equal and the effect of averaging the incidence angles in two reflections can be achieved better.

Namely, in the case of the configuration where the third folding member is disposed between the second imaging optical system and the third imaging optical system and where the fourth folding member is disposed between the fifth imaging optical system and the sixth imaging optical system, an imaging magnification β3 of the third imaging optical system and an imaging magnification β6 of the sixth imaging optical system may satisfy Condition Expressions (3) and (4) below. It is, however, assumed herein that there is no point optically conjugate with a point which is on the first surface and at which an optical axis intersects with the first surface in the optical path between the second conjugate point and the third conjugate point and that there is no point optically conjugate with a point which is on the second surface and at which an optical axis intersects with the second surface in the optical path between the fifth conjugate point and the sixth conjugate point.

0.5<|β3|<2.0 (3)

0.5<|β6|<2.0 (4)

Alternatively, in the case of the configuration where the third folding member is disposed between the first imaging optical system and the second imaging optical system and where the fourth folding member is disposed between the fourth imaging optical system and the fifth imaging optical system, an imaging magnification β23 of a composite optical system consisting of the second imaging optical system and the third imaging optical system and an imaging magnification β56 of a composite optical system consisting of the fifth imaging optical system and the sixth imaging optical system can satisfy Condition Expressions (5) and (6) below. It is, however, assumed herein that there is no point optically conjugate with a point which is on the first surface and at which an optical axis intersects with the first surface except for the second conjugate point in the optical path between the third conjugate point and the first conjugate point and that there is no point optically conjugate with a point which is on the second surface and at which an optical axis intersects with the second surface except for the fifth conjugate point in the optical path between the sixth conjugate point and the fourth conjugate point.

0.5<|β23|<2.0 (5)

0.5<|β56|<2.0 (6)

When the Condition Expressions (3)-(6) are not satisfied, it will become difficult to suppress the influence of the incidence angle characteristics of the reflecting surfaces of the respective folding members and deterioration of imaging performance will cause a line width difference between a vertical pattern and a horizontal pattern to be formed in the same line width or cause a line width difference between two isolated equal-width lines. For better achieving the effects of the embodiment of the present invention, the lower limit of Condition Expressions (3)-(6) can be set to 0.8. For better achieving the effects of the embodiment of the present invention, the upper limit of Condition Expressions (3)-(6) can be set to 1.6.

When the projection optical system of the embodiment of the present invention is arranged so that a normal to the reflecting surface of each folding member makes 45° relative to the optical axis, it can satisfy Condition Expression (7) below, where A3 is an angle of incidence of a ray emitted from the first effective field region on the first surface, to the reflecting surface of the third folding member and A1 is an angle of incidence of the same ray to the reflecting surface of the first folding member. Furthermore, the projection optical system may satisfy Condition Expression (8) below, where A4 is an angle of incidence of a ray emitted from the second effective field region on the second surface, to the reflecting surface of the fourth folding member and A2 is an angle of incidence of the same ray to the reflecting surface of the second folding member.

70°<(A1+A3)<110° (7)

70°<(A2+A4)<110° (8)

Condition Expressions (7) and (8) are condition expressions for directly defining a required range of the difference between α and α′ necessary for maintaining the good imaging performance while suppressing the influence of the incidence angle characteristics of the reflecting surfaces of the respective folding members. For better achieving the effects of the embodiment of the present invention, the lower limit of Condition Expressions (7) and (8) can be set to 80°. For better achieving the effects of the embodiment of the present invention, the upper limit of Condition Expressions (7) and (8) can be set to 105°.

When beams incident to the reflecting surfaces of the respective folding members are telecentric in the projection optical system of the embodiment of the present invention, it is feasible to suppress variation in imaging performance in the effective image regions on the image plane. When the angle between the optical axis and a principal ray incident to the reflecting surface of each folding member is larger than 5°, a relatively large difference is made in imaging performance in the effective image region. On this occasion, the concave reflecting mirrors may be disposed near the pupil positions of the second imaging optical system and the fifth imaging optical system, and the second imaging optical system and the fifth imaging optical system each may have a positive lens as a field lens for condensing telecentric principal rays.

Specifically, in the case of the configuration where the third folding member is disposed between the second imaging optical system and the third imaging optical system and where the fourth folding member is disposed between the fifth imaging optical system and the sixth imaging optical system, it is feasible to adopt a configuration wherein the third imaging optical system and the sixth imaging optical system are optical systems telecentric on the entrance side and on the exit side and wherein an angle between the optical axis and a principal ray from each point in the first effective field region on the first surface upon incidence to the third imaging optical system and an angle between the optical axis and a principal ray from each point in the first effective field region upon exiting from the third imaging optical system both are not more than 5°. Similarly, an angle between the optical axis and a principal ray from each point in the second effective field region on the second surface upon incidence to the sixth imaging optical system and an angle between the optical axis and a principal ray from each point in the second effective field region upon exiting from the sixth imaging optical system both may not be more than 5°.

Alternatively, in the case of the configuration where the third folding member is disposed between the first imaging optical system and the second imaging optical system and where the fourth folding member is disposed between the fourth imaging optical system and the fifth imaging optical system, it is feasible to adopt a configuration wherein the second imaging optical system and the fifth imaging optical system are optical systems telecentric on the entrance side and wherein the third imaging optical system and the sixth imaging optical system are optical systems telecentric on the exit side. Furthermore, an angle between the optical axis and a principal ray from each point in the first effective field region on the first surface upon incidence to the second imaging optical system and an angle between the optical axis and a principal ray from each point in the first effective field region upon exiting from the third imaging optical system both may not be more than 5°. Similarly, an angle between the optical axis and a principal ray from each point in the second effective field region on the second surface upon incidence to the fifth imaging optical system and an angle between the optical axis and a principal ray from each point in the second effective field region upon exiting from the sixth imaging optical system both may not be more than 5°.

When the projection optical system of the embodiment of the present invention having the configuration as described above is applied to an exposure apparatus, a first mask set on the first surface, a second mask set on the second surface, and a wafer set on the third surface are arranged on the same side with respect to the projection optical system. Namely, in the projection optical system of the embodiment of the present invention, a direction of principal rays emitted from the first surface and the second surface is opposite to a direction of principal rays incident to the third surface.

When we consider a configuration of a mask stage to move while holding a mask and a wafer stage to move while holding a wafer, it is important in the embodiment of the present invention that the first surface, the second surface, and the third surface extend horizontally in a space below the projection optical system and that the third surface be located below the first surface and the second surface. This configuration makes it feasible, for example, to avoid interference between the mask stage holding the mask by suction from the top against gravity and the wafer stage with the wafer thereon. Namely, a movement space being a space necessary for movement of the mask stage can be separated from a movement space being a space necessary for movement of the mask stage. Particularly, when the projection optical system adopts a configuration wherein the first surface and the second surface are located on an identical plane and a configuration wherein the first surface, the second surface, and the third surface extend horizontally, the configuration of the optical system can be further simplified.

Specifically, the projection optical system of the embodiment of the present invention may satisfy Condition Expressions (9), (10), and (11) below. In Condition Expressions (9)-(11), D1 is an axial distance between the third surface and an intersection between the reflecting surface of the first folding member and the optical axis of the seventh imaging optical system, and D2 an axial distance between the third surface and an intersection between the reflecting surface of the second folding member and the optical axis of the seventh imaging optical system. Furthermore, D3 is an axial distance between the first surface and an intersection between the reflecting surface of the third folding member and the optical axis of the first imaging optical system, and D4 an axial distance between the second surface and an intersection between the reflecting surface of the fourth folding member and the optical axis of the fourth imaging optical system. In the present specification, however, an intersection between a reflecting surface of a folding member and an optical axis of a corresponding imaging optical system means an intersecting point between a virtual extension of the reflecting surface and the optical axis.

D3≦D1 (9)

D4≦D2 (10)

D1=D2 (11)

When we consider increase in the size of the wafer, i.e., readiness for 450 mm wafer, an increase in the size of the wafer stage is inevitable in future exposure apparatus. Therefore, the projection optical system of the embodiment of the present invention may satisfy Condition Expressions (12) and (13) below. In Condition Expressions (12) and (13), D13 is a distance along the optical axis of the third imaging optical system between an intersection between the reflecting surface of the first folding member and the optical axis of the seventh imaging optical system and an intersection between the reflecting surface of the third folding member and the optical axis of the first imaging optical system. Furthermore, D24 is a distance along the optical axis of the sixth imaging optical system between an intersection between the reflecting surface of the second folding member and the optical axis of the seventh imaging optical system and an intersection between the reflecting surface of the fourth folding member and the optical axis of the fourth imaging optical system. In addition, S represents a maximum diameter of a circle circumscribed to a wafer (photosensitive substrate).

2.2<D13/S<5.0 (12)

2.2<D24/S<5.0 (13)

When the ratios are smaller than the lower limit of Condition Expressions (12) and (13), the space between the mask stage and the wafer stage will be too small and it will be difficult to avoid interference between the stages. When the ratios are larger than the upper limit of Condition Expressions (12) and (13), the space between the mask stage and the wafer stage will be too large and it will lead to an increase in the scale of the apparatus. For better achieving the effects of the embodiment of the present invention, the lower limit of Condition Expressions (12) and (13) can be set to 2.4. For better achieving the effects of the embodiment of the present invention, the upper limit of Condition Expressions (12) and (13) can be set to 4.2.

In the projection optical system of the embodiment of the present invention, the optical path between the projection optical system and the image plane can be filled with a liquid. When the liquid immersion type configuration with a liquid immersion region on the image side is adopted, it is feasible to secure a relatively large effective image region while ensuring a large effective image-side numerical aperture.

In the projection optical system of the embodiment of the present invention, when the first folding member and the second folding member as a path combining device are integrally configured, it is feasible to achieve simplification and stabilization of the optical system. In the projection optical system of the embodiment of the present invention, a ridge line formed by the reflecting surface of the first folding member and the reflecting surface of the second folding member can be located on a point of intersection among the optical axis of the third imaging optical system, the optical axis of the sixth imaging optical system, and the optical axis of the seventh imaging optical system. More precisely, a ridge line formed by a virtual extension of the planar reflecting surface of the first folding member and a virtual extension of the planar reflecting surface of the second folding member can be located on a point of intersection among the exit-side optical axis of the third imaging optical system, the exit-side optical axis of the sixth imaging optical system, and the entrance-side optical axis of the seventh imaging optical system. In this case, the first folding member and the second folding member can suitably separate rays traveling from the third imaging optical system to the seventh imaging optical system, from rays traveling from the sixth imaging optical system to the seventh imaging optical system. The above description is not applicable only to the projection optical system of the first aspect but also applicable to the projection optical system of the second aspect.

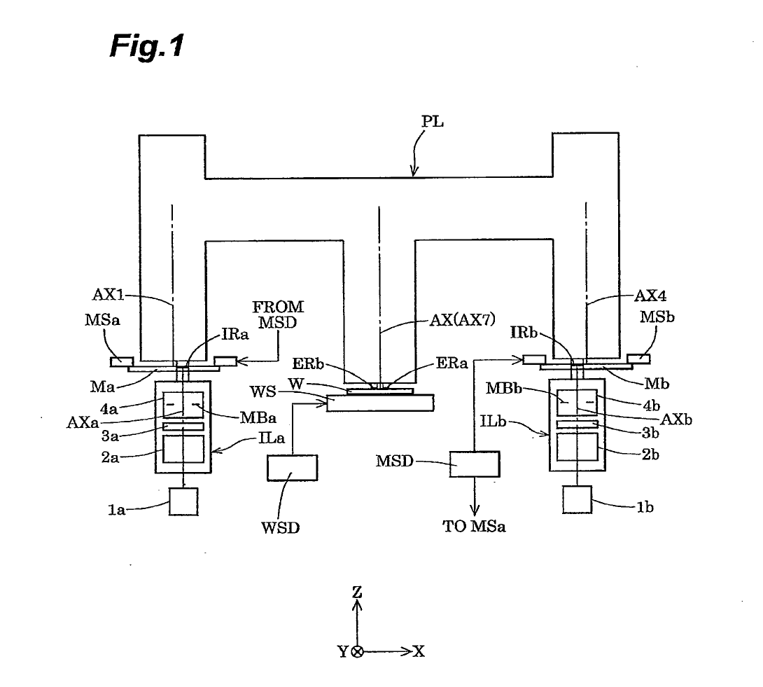

An embodiment of the present invention will be described based on the accompanying drawings. FIG. 1 is a drawing schematically showing a configuration of an exposure apparatus according to the embodiment of the present invention. In FIG. 1, the Z-axis is set along a direction of a normal to an exposure surface (transfer surface) of a wafer W being a photosensitive substrate, the X-axis along a direction parallel to the plane of FIG. 1 in the exposure surface of the wafer W, and the Y-axis along a direction normal to the plane of FIG. 1 in the exposure surface of the wafer W. With reference to FIG. 1, the exposure apparatus of the present embodiment has two illumination systems ILa and ILb arranged with a space in the X-direction.

Since the first illumination system ILa and the second illumination system ILb arranged in parallel have the same configuration, the bellow will describe the configuration and action of each illumination system with focus on the first illumination system ILa, and the reference sign of the corresponding second illumination system and reference signs of constituent elements thereof will be given in parentheses. The first illumination system ILa (second illumination system ILb) has a first optical system 2a (2b), a fly's eye lens (or micro fly's eye lens) 3a (3b), and a second optical system 4a (4b). A light source 1a (1b) for supplying exposure light (illumination light) to the first illumination system ma (second illumination system ILb) is an ArF excimer laser light source which supplies light with the wavelength of about 193 nm. It is also possible to use a common light source to the first illumination system ILa and the second illumination system ILb.

A nearly parallel beam emitted from the light source 1a (1b) travels through the first optical system 2a (2b) to enter the fly's eye lens 3a (3b). The first optical system 2a (2b) has, for example, a beam sending system (not shown) having a well-known configuration, a polarization state varying section (not shown), and so on. The beam sending system has functions to guide an incident beam to the polarization state varying section while converting the incident beam into a beam having a cross section of an appropriate size and shape, and to actively correct positional variation and angular variation of the beam incident to the polarization state varying section.

The polarization state varying section has a function to change a polarization state of the illumination light incident to the fly's eye lens 3a (3b). Specifically, the polarization state varying section converts linearly polarized light incident from the beam sending system, into linearly polarized light with a different direction of vibration, or converts linearly polarized light incident thereto, into unpolarized light, or directly emits the incident linearly polarized light without conversion. The beam the polarization state of which has been converted according to need by the polarization state varying section is then incident to the fly's eye lens 3a (3b).

The beam entering the fly's eye lens 3a (3b) is two-dimensionally divided by a large number of micro lens elements and small illuminants are formed on respective rear focal planes of the micro lens elements to which the beam was incident. In this manner, a substantial surface illuminant consisting of the large number of small illuminants is formed on the rear focal plane of the fly's eye lens 3a (3b). Beams from the fly's eye lens 3a (3b) are guided through the second optical system 4a (4b) to a first mask Ma (second mask Mb).

The second optical system 4a (4b) has, for example, a condenser optical system (not shown) having a well-known configuration, a mask blind MBa (MBb), an imaging optical system (not shown), and so on. In this case, the beams from the fly's eye lens 3a (3b) travel through the condenser optical system to illuminate the mask blind MBa (MBb) as superimposed thereon. An illumination field of a rectangular shape according to the shape of each micro lens element forming the fly's eye lens 3a (3b) is formed on the mask blind as a field illumination stop. Beams passing through a rectangular aperture (light transmitting portion) of the mask blind MBa (MBb) travel through the imaging optical system to illuminate the first mask Ma (second mask Mb) as superimposed thereon.

A beam transmitted by the first mask Ma and a beam transmitted by the second mask Mb travel through the double-headed projection optical system PL to form a pattern image of the first mask Ma and a pattern image of the second mask Mb, respectively, on the wafer (photosensitive substrate) W. The first mask stage MSa and the second mask stage MSb hold the first mask Ma and the second mask Mb, respectively, so that a pattern surface thereof extends along the XY plane (horizontal plane). Specifically, the masks Ma and Mb are held by suction from the top against gravity by the respective mask stages MSa and MSb. The mask stages MSa and MSb are connected to a mask stage driving system MSD. The mask stage driving system MSD drives the mask stages MSa and MSb in the X-direction, the Y-direction, and a direction of rotation around the Z-direction.

It is not limited to the mask stage holding the mask by suction from the top as mask stages MSa and MSb, and a mask stage holding a mask from the bottom is applicable.

The wafer W is held on a wafer stage WS so that an exposure surface thereof extends along the XY plane. The wafer stage WS is connected to a wafer stage driving system WSD. The wafer stage driving system WSD drives the wafer stage WS in the X-direction, the Y-direction, the Z-direction, and a direction of rotation around the Z-direction. The projection optical system PL is an optical system having two effective fields separated from each other along the X-direction, and one effective image region. The internal configuration of the projection optical system PL will be described later.

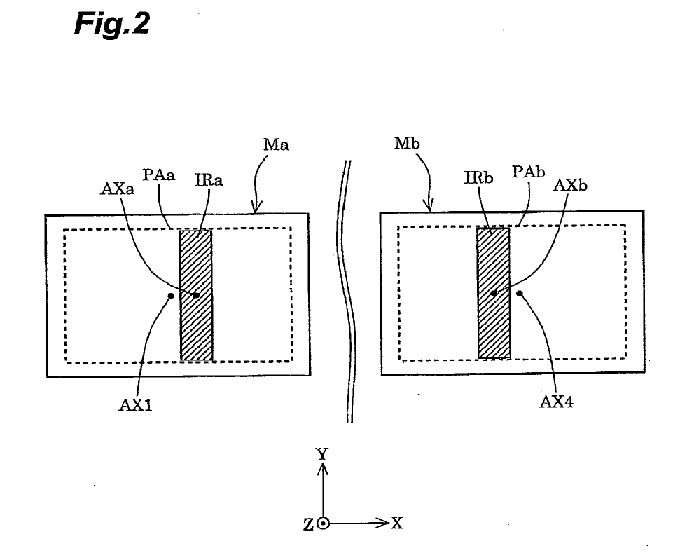

In the present embodiment, the first illumination system ILa forms a rectangular illumination region IRa elongated in the Y-direction on the first mask Ma, as shown on the left in FIG. 2. The second illumination system ILb forms a rectangular illumination region IRb elongated in the Y-direction on the second mask Mb, as shown on the right in FIG. 2. The first illumination region IRa and the second illumination region IRb are formed, for example, as centered on the optical axis AXa of the first illumination system Ma and on the optical axis AXb of the second illumination system ILb, respectively.

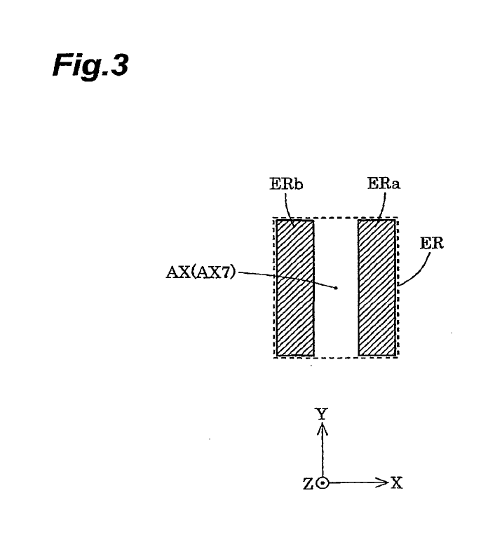

Namely, a pattern corresponding to the first illumination region IRa, in a pattern region PAa of the first mask Ma is illuminated under a predetermined illumination condition by the first illumination system ILa. A pattern corresponding to the second illumination region IR2, in a pattern region PAb of the second mask Mb separated along the X-direction from the first mask Ma, is illuminated under a predetermined illumination condition by the second illumination system ILb. In this manner, as shown in FIG. 3, a pattern image of the first mask Ma illuminated by the first illumination region IRa is formed in a rectangular first region (first effective image region) ERa elongated in the Y-direction in an effective image region ER of the projection optical system PL, and a pattern image of the second mask Mb illuminated by the second illumination region IRb is formed in a second region (second effective image region) ERb having a rectangular contour similarly elongated in the Y-direction and located in parallel with the first region ERa in the effective image region ER.

In the present embodiment, while the first mask Ma, the second mask Mb, and the wafer W are synchronously moved along the X-direction relative to the projection optical system PL, one shot area on the wafer W is subjected to scanning exposure with superposition of the pattern of the first mask Ma and the pattern of the second mask Mb to form one composite pattern. The foregoing superposition scanning exposure is repeated while two-dimensionally stepping the wafer W along the XY plane relative to the projection optical system PL, whereby the composite pattern of the pattern of the first mask Ma and the pattern of the second mask Mb is sequentially formed in each of shot areas on the wafer W.

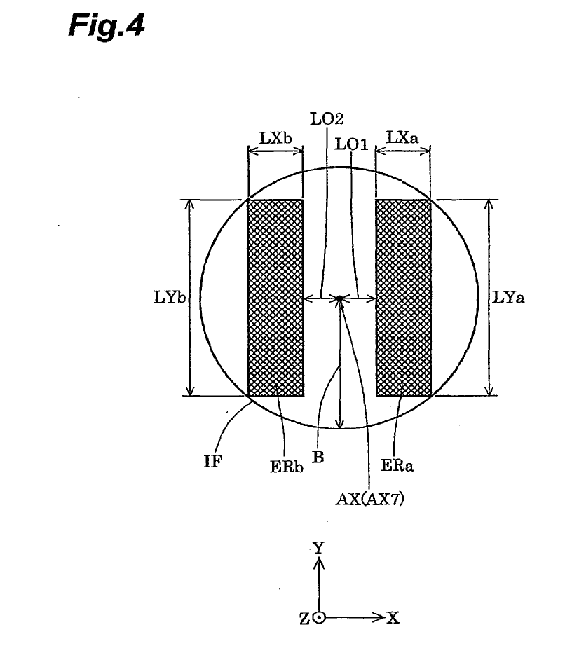

FIG. 4 is a drawing showing a positional relation among the reference optical axis, and the rectangular still exposure regions formed on the wafer in the present embodiment. In the present embodiment, as shown in FIG. 4, a first still exposure region (corresponding to the first effective image region) ERa of a rectangular shape having a predetermined size is set at a position apart by an offset LO1 in the +X-direction from the reference optical axis AX, and a second still exposure region (corresponding to the second effective image region) ERb of a rectangular shape having a predetermined size is set at a position apart by an offset LO2 in the −X-direction from the reference optical axis AX, in a region of a circular shape (image circle) IF centered on the reference optical axis AX (agreeing with the optical axis AX7 on the wafer W) and having a radius B. The first still exposure region ERa and the second still exposure region ERb are symmetrical with respect to an axis passing the reference optical axis AX and being parallel to the Y-axis.

The X-directional lengths of the still exposure regions ERa, ERb are LXa, LXb (=LXa) and the Y-directional lengths thereof are LYa, LYb (=LYa). Therefore, as shown in FIG. 2, the rectangular first illumination region (corresponding to the first effective field region) IRa having the size and shape according to the first still exposure region ERa is formed at a position apart by a distance corresponding to the offset LO1 in the +X-direction from the optical axis AX1 of the first imaging optical system, corresponding to the rectangular first still exposure region ERa, on the first mask Ma. Similarly, the rectangular second illumination region (corresponding to the second effective field region) IRb having the size and shape according to the second still exposure region ERb is formed at a position apart by a distance corresponding to the offset LO2 (=LO1) in the −X-direction from the optical axis AX4 of the fourth imaging optical system, corresponding to the rectangular second still exposure region ERb, on the second mask Mb.

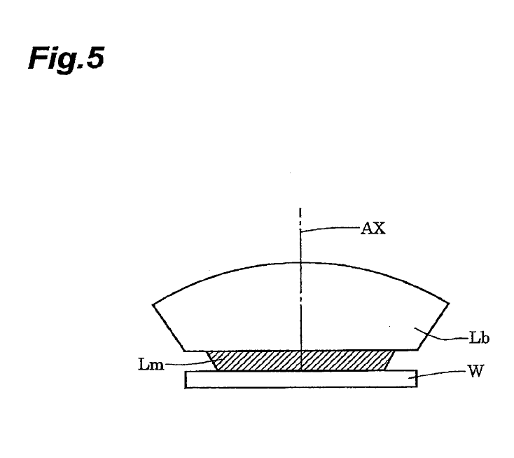

FIG. 5 is a drawing schematically showing a configuration between a boundary lens and a wafer in the present embodiment. With reference to FIG. 5, the projection optical system PL of the present embodiment is configured so that the optical path between the boundary lens Lb and the wafer W is filled with a liquid Lm. In the present embodiment, the liquid Lm used is pure water (deionized water) readily available in a large amount in semiconductor manufacturing facilities and others. It is, however, also possible to use water containing Cs⁺, K⁺, Cl⁻, SO₄²⁻, or PO₄²⁻, isopropanol, glycerol, hexane, heptane, decane, or the like as the liquid Lm.

In the exposure apparatus of the step-and-scan method performing scanning exposure while moving the wafer W relative to the projection optical system PL, the liquid Lm can continue to fill the interior of the optical path between the boundary lens Lb and the wafer W in the projection optical system PL from a start to an end of the scanning exposure, for example, by making use of the technology disclosed in International Publication WO99/49504, the technology disclosed in Japanese Patent Application Laid-open No. 10-303114, or the like. In the technology disclosed in International Publication WO99/49504, the liquid controlled at a predetermined temperature is supplied through a supply tube and discharge nozzle from a liquid supply device so as to fill the optical path between the boundary lens Lb and the wafer W and the liquid is collected from on the wafer W through a collection tube and inflow nozzle by a liquid collecting device.

Teachings of international Publication WO99/49504 and Japanese Patent Application Laid-open No. 10-303114 are incorporated as references herein.

In the present embodiment, a supply/drain mechanism is used to circulate the liquid Lm in the optical path between the boundary lens Lb and the wafer W. As the liquid Lm as an immersion liquid is circulated at a small flow rate in this manner, it is feasible to prevent deterioration of the liquid by effects of antisepsis, prevention of mold, and so on. It is also feasible to prevent aberration variation due to absorption of heat of the exposure light.

Other applicable techniques for keeping the liquid in the optical path between the projection optical system and the photosensitive substrate as described above include the techniques of locally filling the optical path with the liquid and such techniques as a technique of moving a stage holding a substrate as an exposure object in a liquid bath as disclosed in Japanese Patent Application Laid-open No. 6-124873, and a technique of forming a liquid bath in a predetermined depth on a stage and holding the substrate therein as disclosed in Japanese Patent Application Laid-open No. 10-303114.

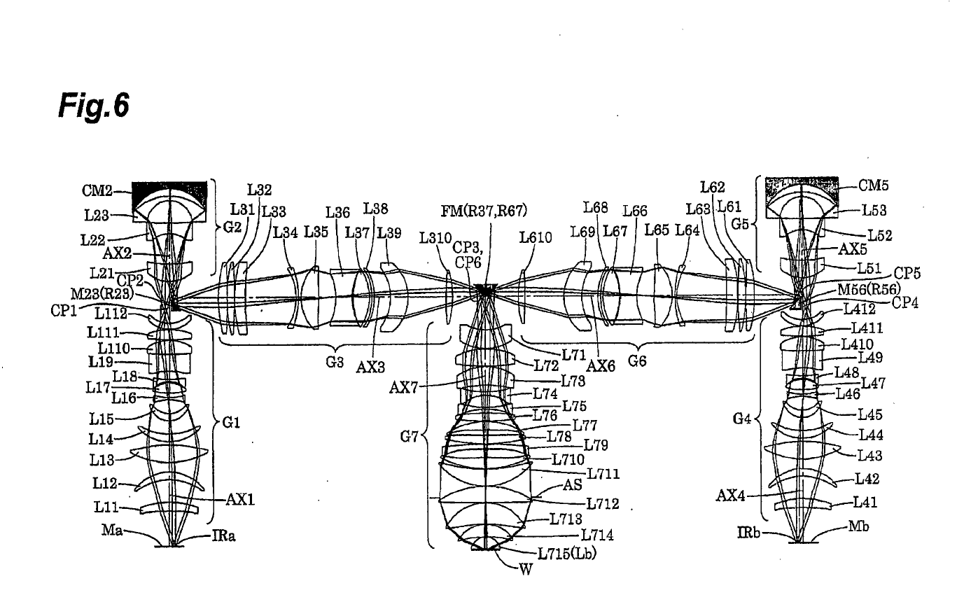

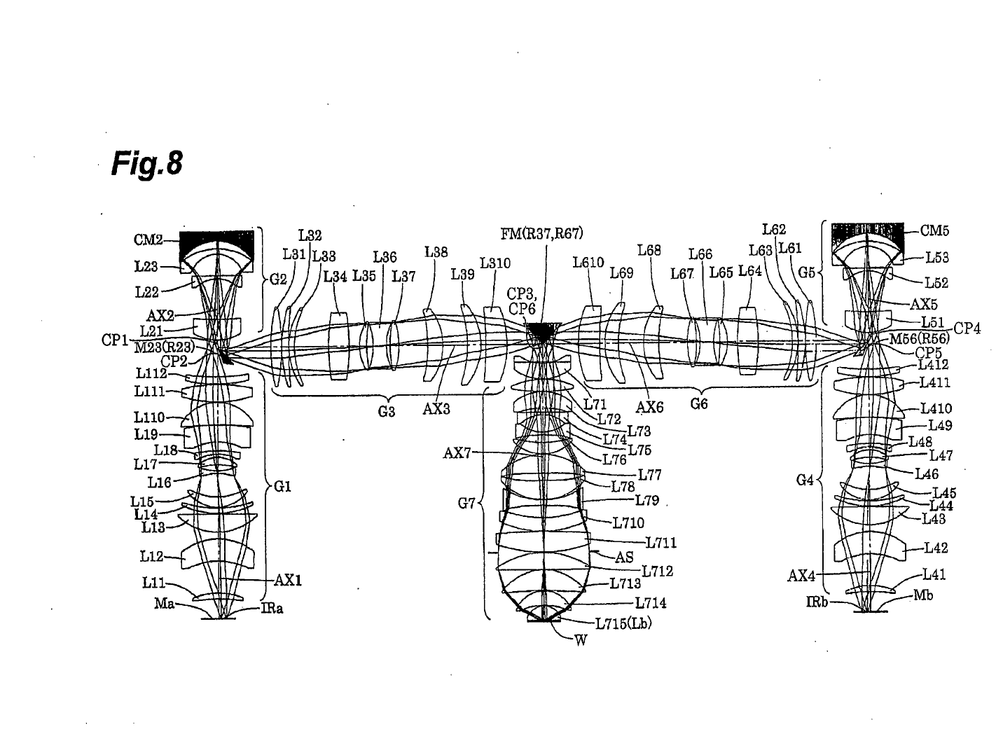

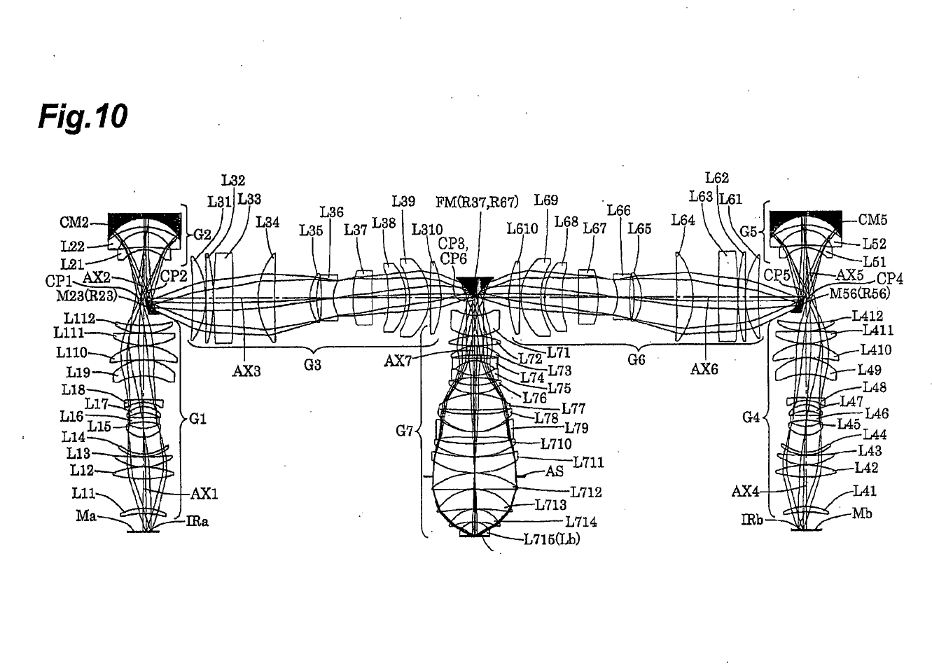

In each of examples of the present embodiment, the projection optical system PL, as shown in FIG. 6, FIG. 8, and FIG. 10 below, comprises a first imaging optical system G1, a second imaging optical system G2, a third imaging optical system G3, a fourth imaging optical system G4, a fifth imaging optical system G5, a sixth imaging optical system G6, a seventh imaging optical system G7, a reflecting mirror FM having a reflecting surface R37 and a reflecting surface R67, a plane reflecting mirror M23 (third folding member) having a reflecting surface R23, and a plane reflecting mirror M56 (fourth folding member) having a reflecting surface R56.

The first imaging optical system G1 is disposed in an optical path between the first mask Ma and a first conjugate point CP1 optically conjugate with a point which is on the first mask Ma and at which an optical axis intersects with the first mask Ma (entrance-side optical axis AX1 of the first imaging optical system G1). The second imaging optical system G2 is disposed in an optical path between the first conjugate point CP1 and a second conjugate point CP2 optically conjugate with the point which is on the first mask Ma and at which an optical axis intersects with the first mask Ma. The third imaging optical system G3 is disposed in an optical path between the second conjugate point CP2 and a third conjugate point CP 3 optically conjugate with the point which is on the first mask Ma and at which an optical axis intersects with the first mask Ma.

The fourth imaging optical system G4 is disposed in an optical path between the second mask Mb and a fourth conjugate point CP4 optically conjugate with a point which is on the second mask Mb and at which an optical axis intersects with the second mask Mb (entrance-side optical axis AX4 of the fourth imaging optical system G4). The fifth imaging optical system G5 is disposed in an optical path between the fourth conjugate point CP4 and a fifth conjugate point CP5 optically conjugate with the point which is on the second mask Mb and at which an optical axis intersects with the second mask Mb. The sixth imaging optical system G6 is disposed in an optical path between the fifth conjugate point CP5 and a sixth conjugate point CP6 optically conjugate with the point which is on the second mask Mb and at which an optical axis intersects with the second mask Mb.

The seventh imaging optical system G7 is disposed in an optical path between the wafer W and the third and sixth conjugate points CP3, CP6. The reflecting mirror FM is a path combining device consisting of the first folding member disposed near the third conjugate point CP3 and having the planar reflecting surface R37 and the second folding member disposed near the sixth conjugate point CP6 and having the planar reflecting surface R67. The plane reflecting mirror M23 is disposed near the second conjugate point CP2 and the plane reflecting mirror M56 is disposed near the fifth conjugate point CP5.

The first imaging optical system G1, third imaging optical system G3, fourth imaging optical system G4, sixth imaging optical system G6, and seventh imaging optical system G7 are refractive systems. The second imaging optical system G2 and fifth imaging optical system G5 are catadioptric systems (reflection/refraction optical systems) including a concave reflecting mirror. The first optical unit from the first imaging optical system G1 to the third imaging optical system G3 and the second optical unit from the fourth imaging optical system G4 to the sixth imaging optical system G6 have the same configuration and are arranged in symmetry with respect to the optical axis AX7 of the seventh imaging optical system G7.

In the reflecting mirror FM as a path combining device, a ridge line formed by the reflecting surface R37 and the reflecting surface 67 (more precisely, a ridge line formed by a virtual extension of the reflecting surface R37 and a virtual extension of the reflecting surface R67) is located on a point of intersection among the exit-side optical axis AX3 of the third imaging optical system G3, the exit-side optical axis AX6 of the sixth imaging optical system G6, and the entrance-side optical axis AX7 of the seventh imaging optical system G7. The projection optical system PL is telecentric both on the object side and on the image side.

In the projection optical system PL of each example, light traveling along the +Z-direction from the first mask Ma travels through the first imaging optical system G1 to form a first intermediate image. Light from the first intermediate image travels through the second imaging optical system G2 to form a second intermediate image near the reflecting surface R23 of the plane reflecting mirror M23. Light from the second intermediate image or light forming the second intermediate image is folded to the +X-direction by the reflecting surface R23 and then travels through the third imaging optical system G3 to form a third intermediate image near the reflecting surface R37 of the reflecting mirror FM.

Similarly, light traveling along the −Z-direction from the second mask Mb travels through the fourth imaging optical system G4 to form a fourth intermediate image. Light from the fourth intermediate image travels through the fifth imaging optical system G5 to form a fifth intermediate image near the reflecting surface R56 of the plane reflecting mirror M56. Light from the fifth intermediate image or light forming the fifth intermediate image is folded to the −X-direction by the reflecting surface R56 to form a sixth intermediate image near the reflecting surface R67 of the reflecting mirror FM.

Light from the third intermediate image or light forming the third intermediate image is folded to the −Z-direction by the reflecting surface R37 of the reflecting mirror FM and then travels through the seventh imaging optical system G7 to form a final first reduced image on the wafer W. Light from the sixth intermediate image or light forming the sixth intermediate image is folded to the −Z-direction by the reflecting surface R67 of the reflecting mirror FM and then travels through the seventh imaging optical system G7 to form a final second reduced image at a position parallel to the first reduced image on the wafer W.

In each of the examples of the present embodiment, an aspherical surface is represented by Formula (a) below, where y is a height in a direction perpendicular to the optical axis, z a distance (sag) along the optical axis from a tangent plane at a top of the aspherical surface to a position on the aspherical surface at height y, r a radius of curvature at the top, ic the conic constant, and Cₙ the nth aspherical coefficient. In Tables (1), (2), and (3) below, each lens surface formed in the aspherical shape is accompanied by mark * on the right of a surface number.

z=(y²/r)/[1+{1−(1+κ)·y²/r²}^{1/2}]+C₄·y⁴+C₆·y⁶+C₈·y⁸+C₁₀·y¹⁰+C₁₂·y¹²+C₁₄·y¹⁴+C₁₆·y¹⁶+C₁₈·y¹⁸+C₂₀·y²⁰ (a)

### First Example

FIG. 6 is a drawing showing a lens configuration of the projection optical system according to the first example of the embodiment. With reference to FIG. 6, in the projection optical system 15. PL of the first example the first imaging optical system G1 is composed of twelve lenses L11-L112 arranged in order from the entrance side of light along the optical axis AX1 extending in the Z-direction. The second imaging optical system G2 is composed of one positive lens L21, two negative lenses L22 and L23, and a concave reflecting mirror CM2 arranged in order from the entrance side of light along the optical axis AX2 lying on the same straight line as the optical axis AX1. The third imaging optical system G3 is composed of ten lenses L31-L310 arranged in order from the entrance side of light along the optical axis AX3 extending in the X-direction.

The fourth imaging optical system G4, fifth imaging optical system G5, and sixth imaging optical system G6 have the same configurations as the first imaging optical system G1, second imaging optical system G2, and third imaging optical system G3, respectively, and therefore the description of the configurations is omitted herein. The seventh imaging optical system G7 is composed of fifteen lenses L71-L715 arranged in order from the entrance side of light along the optical axis AX7 extending in the Z-direction. The planoconvex lens L715 arranged nearest to the wafer in the seventh imaging optical system G7 constitutes a boundary lens Lb. In the first example, there is a paraxial pupil position inside the lens L712 and an aperture stop AS is arranged at this paraxial pupil position.

In the first example, the optical path between the boundary lens Lb and the wafer W is filled with pure water (Lm) having the refractive index of 1.435876 for the ArF excimer laser light (wavelength λ=193.306 nm) of used light (exposure light). All optically transparent members (lenses) are made of silica glass (SiO₂) having the refractive index of 1.5603261 for the used light.

Table (1) below provides values of specifications of the projection optical system PL according to the first example. In the main specifications of Table (1), λ represents the center wavelength of the exposure light, β a magnitude of projection magnification, NA the image-side (wafer-side) numerical aperture, B a radius (maximum image height) of image circle IF on the wafer W, LXa and LXb lengths along the X-direction of the still exposure regions ERa, ERb (lengths of the long sides), and LYa and LYb lengths along the Y-direction of the still exposure regions ERa, ERb (lengths of the short sides).

In the specifications of optical members in Table (1), the surface number represents an order of a surface from the entrance side of light, r a radius of curvature of each surface (radius of curvature at a top in the case of an aspherical surface: mm), d an axial distance of each surface or surface separation (mm), and n the refractive index for the center wavelength. Since the imaging optical systems G1-G3 and the imaging optical systems G4-G6 have the same configurations, Table (1) includes no description of specifications of optical members about the imaging optical systems G4-G6, while showing only reference signs of the optical members forming the imaging optical systems G4-G6, in parentheses. The same notations in Table (1) also apply to Tables (2) and (3) below.

TABLE (1)
(Main Specs)

λ = 193.306 nm
β = ¼
NA = 1.40
B = 15.3 mm
LO1 = LO2 = 3.8 mm
LXa = LXb = 26 mm
LYa = LYb = 4 mm

(Specs of Optical Members)

| Surface No. | r | d | n | Optical Member |
|---|---|---|---|---|
| | (mask surface) | 143.0457 | | |
| 1* | −2149.56686 | 37.1696 | 1.5603261 | L11(L41) |
| 2 | −353.06239 | 90.4783 | | |
| 3 | −242.13440 | 31.5726 | 1.5603261 | L12(L42) |
| 4 | −189.60199 | 38.7034 | | |
| 5 | 349.23635 | 70.5353 | 1.5603261 | L13(L43) |
| 6 | −625.88405 | 13.8602 | | |
| 7 | 186.71555 | 30.8278 | 1.5603261 | L14(L44) |
| 8 | 263.87455 | 53.2551 | | |
| 9 | 87.62478 | 28.7960 | 1.5603261 | L15(L45) |
| 10 | 88.73819 | 56.9253 | | |
| 11 | −243.47842 | 9.0000 | 1.5603261 | L16(L46) |
| 12 | 233.40002 | 18.0896 | | |
| 13 | 257.66874 | 42.3077 | 1.5603261 | L17(L47) |
| 14 | −110.87886 | 4.7153 | | |
| 15 | −103.85652 | 10.5712 | 1.5603261 | L18(L48) |
| 16 | 446.35518 | 32.5621 | | |
| 17* | −291.92989 | 67.8050 | 1.5603261 | L19(L49) |
| 18 | 908.08203 | 1.0000 | | |
| 19 | 1185.15814 | 58.2193 | 1.5603261 | L110(L410) |
| 20 | −166.95773 | 1.0000 | | |
| 21 | 726.06659 | 41.7689 | 1.5603261 | L111(L411) |
| 22 | −267.26042 | 1.0000 | | |
| 23 | 125.76600 | 25.0172 | 1.5603261 | L112(L412) |
| 24* | 125.78727 | 100.0000 | | |
| 25 | ∞ | 25.0000 | | virtual surface |
| 26 | ∞ | 44.5922 | | virtual surface |
| 27 | 143.24159 | 69.9979 | 1.5603261 | L21(L51) |
| 28 | 439.36418 | 124.4664 | | |
| 29 | −118.61450 | 45.1287 | 1.5603261 | L22(L52) |
| 30 | 2386.01920 | 90.2866 | | |
| 31 | −97.15320 | 18.0000 | 1.5603261 | L23(L53) |
| 32 | −221.08990 | 30.5668 | | |
| 33 | −177.50172 | −30.5668 | | CM2(CM5) |
| 34 | −221.08990 | −18.0000 | 1.5603261 | L23(L53) |
| 35 | −97.15320 | −90.2866 | | |
| 36 | 2386.01920 | −45.1287 | 1.5603261 | L22(L52) |
| 37 | −118.61450 | −124.4664 | | |
| 38 | 439.36418 | −69.9979 | 1.5603261 | L21(L51) |
| 39 | 143.24159 | −44.5922 | | |
| 40 | ∞ | −25.0000 | | virtual surface |
| 41 | ∞ | −206.7836 | | R23(R56) |
| 42 | −507.99489 | −37.3768 | 1.5603261 | L31(L61) |
| 43 | 5329.19532 | −1.0000 | | |
| 44 | −597.00952 | −32.1771 | 1.5603261 | L32(L62) |
| 45 | 1912.09613 | −1.0000 | | |
| 46 | −547.26791 | −46.0467 | 1.5603261 | L33(L63) |
| 47 | −1355.78569 | −216.9752 | | |
| 48 | 204.62751 | −9.0389 | 1.5603261 | L34(L64) |
| 49 | 347.59776 | −11.6879 | | |
| 50 | −176.51690 | −76.0000 | 1.5603261 | L35(L65) |
| 51* | 910.10858 | −74.9718 | | |
| 52 | 204.45425 | −70.4619 | 1.5603261 | L36(L66) |
| 53 | −226.72267 | −4.9657 | | |
| 54 | −258.53441 | −69.1045 | 1.5603261 | L37(L67) |
| 55 | 206.04691 | −11.3231 | | |
| 56* | 266.69085 | −11.0620 | 1.5603261 | L38(L68) |
| 57 | 221.04482 | −69.0824 | | |
| 58 | 187.97072 | −75.9659 | 1.5603261 | L39(L69) |
| 59 | 177.05435 | −165.2252 | | |
| 60 | −1672.11676 | −26.8619 | 1.5603261 | L310(L610) |
| 61 | 389.25812 | −141.4648 | | |
| 62 | ∞ | −133.5452 | | R37(R67) |
| 63 | 164.04263 | −76.0000 | 1.5603261 | L71 |
| 64 | 202.32468 | −1.0000 | | |
| 65 | −288.24709 | −71.1250 | 1.5603261 | L72 |
| 66 | 866.33777 | −1.0000 | | |
| 67 | −212.16962 | −76.0000 | 1.5603261 | L73 |
| 68 | −441.31305 | −27.7610 | | |
| 69 | 377.72976 | −14.4786 | 1.5603261 | L74 |
| 70 | −153.07755 | −48.4848 | | |
| 71 | 388.10415 | −9.0000 | 1.5603261 | L75 |
| 72* | −328.65439 | −16.4728 | | |
| 73* | −3157.16360 | −31.4791 | 1.5603261 | L76 |
| 74 | 1168.79047 | −1.0028 | | |
| 75 | −307.09987 | −34.3832 | 1.5603261 | L77 |
| 76* | −3039.32892 | −22.0967 | | |
| 77* | 2000.00000 | −34.9706 | 1.5603261 | L78 |
| 78 | 719.88566 | −1.0000 | | |
| 79 | −1975.23270 | −20.0000 | 1.5603261 | L79 |
| 80* | −2627.98276 | −34.1067 | | |
| 81* | −1484.97943 | −44.1409 | 1.5603261 | L710 |
| 82 | 437.80132 | −1.0000 | | |
| 83 | 720.35508 | −70.1444 | 1.5603261 | L711 |
| 84 | 262.83672 | −1.0000 | | |
| 85 | −378.44582 | −66.0777 | 1.5603261 | L712 |
| 86 | 7570.00418 | 18.0000 | | |
| 87 | ∞ | −19.0000 | | AS |
| 88 | −195.50431 | −85.8176 | 1.5603261 | L713 |
| 89* | −438.12570 | −1.0000 | | |
| 90 | −141.38428 | −50.2383 | 1.5603261 | L714 |
| 91* | −513.84557 | −1.0000 | | |
| 92 | −65.65717 | −49.9000 | 1.5603261 | L715:Lb |
| 93 | ∞ | −3.0000 | 1.435876 | Lm |
| | (wafer surface) | | | |

(aspheric data)
1st surface:

| | |
|---|---|
| κ = 0 | |
| C₄ = −2.56231 × 10⁻⁸ | C₆ = −3.26656 × 10⁻¹³ |
| C₈ = −4.46044 × 10⁻¹⁸ | C₁₀ = −4.40570 × 10⁻²² |
| C₁₂ = −1.99219 × 10⁻²⁷ | C₁₄ = 3.07186 × 10⁻³¹ |
| C₁₆ = −2.10176 × 10⁻³⁵ | C₁₈ = 0 |
| C₂₀ = 0 | |

17th surface:

| | |
|---|---|
| κ = 0 | |
| C₄ = −1.34746 × 10⁻⁸ | C₆ = −3.27663 × 10⁻¹² |
| C₈ = 2.72885 × 10⁻¹⁶ | C₁₀ = −1.38898 × 10⁻¹⁹ |
| C₁₂ = 6.74393 × 10⁻²³ | C₁₄ = −1.94285 × 10⁻²⁶ |
| C₁₆ = 3.35553 × 10⁻³⁰ | C₁₈ = −3.17768 × 10⁻³⁴ |
| C₂₀ = 1.27392 × 10⁻³⁸ | |

24th surface:

| | |
|---|---|
| κ = 0 | |
| C₄ = 2.15631 × 10⁻⁸ | C₆ = 1.03082 × 10⁻¹² |
| C₈ = 4.52407 × 10⁻¹⁷ | C₁₀ = 1.29797 × 10⁻²⁰ |
| C₁₂ = −2.30704 × 10⁻²⁴ | C₁₄ = 4.50350 × 10⁻²⁸ |
| C₁₆ = −3.95702 × 10⁻³² | C₁₈ = 1.78018 × 10⁻³⁶ |
| C₂₀ = 4.91635 × 10⁻⁴³ | |

51st surface:

| | |
|---|---|
| κ = 0 | |
| C₄ = −4.02649 × 10⁻⁸ | C₆ = 6.71563 × 10⁻¹³ |
| C₈ = 7.63744 × 10⁻¹⁸ | C₁₀ = −1.21852 × 10⁻²¹ |
| C₁₂ = 5.22291 × 10⁻²⁵ | C₁₄ = −5.66419 × 10⁻²⁹ |
| C₁₆ = 1.48887 × 10⁻³³ | C₁₈ = 0 |
| C₂₀ = 0 | |

56th surface:

| | |
|---|---|
| κ = 0 | |
| C₄ = 3.05352 × 10⁻⁸ | C₆ = 1.12471 × 10⁻¹² |
| C₈ = 3.98513 × 10⁻¹⁷ | C₁₀ = 1.55839 × 10⁻²¹ |
| C₁₂ = 1.30946 × 10⁻²⁵ | C₁₄ = −1.23576 × 10⁻²⁹ |
| C₁₆ = 2.37280 × 10⁻³³ | C₁₈ = −1.56198 × 10⁻³⁷ |
| C₂₀ = 5.75870 × 10⁻⁴² | |

72nd surface:

| | |
|---|---|
| κ = 0 | |
| C₄ = −4.02946 × 10⁻⁸ | C₆ = 3.02819 × 10⁻¹² |
| C₈ = 2.26081 × 10⁻¹⁷ | C₁₀ = −4.63620 × 10⁻²¹ |
| C₁₂ = −4.32269 × 10⁻²⁵ | C₁₄ = 9.42498 × 10⁻²⁹ |
| C₁₆ = −7.12873 × 10⁻³³ | C₁₈ = 1.93988 × 10⁻³⁷ |
| C₂₀ = 0 | |

73rd surface:

| | |
|---|---|
| κ = 0 | |
| C₄ = −2.35665 × 10⁻⁸ | C₆ = 5.84076 × 10⁻¹³ |
| C₈ = −4.59258 × 10⁻¹⁸ | C₁₀ = −7.00541 × 10⁻²¹ |
| C₁₂ = 1.58454 × 10⁻²⁴ | C₁₄ = −2.57008 × 10⁻²⁸ |
| C₁₆ = 2.61943 × 10⁻³² | C₁₈ = −1.58255 × 10⁻³⁶ |
| C₂₀ = 3.91398 × 10⁻⁴¹ | |

76th surface:

| | |
|---|---|
| κ = 0 | |
| C₄ = −4.57219 × 10⁻¹⁰ | C₆ = −4.37379 × 10⁻¹³ |
| C₈ = −5.22320 × 10⁻¹⁷ | C₁₀ = 4.42637 × 10⁻²² |
| C₁₂ = 1.32814 × 10⁻²⁵ | C₁₄ = −4.37632 × 10⁻³⁰ |
| C₁₆ = −1.67489 × 10⁻³⁵ | C₁₈ = 1.49135 × 10⁻³⁹ |
| C₂₀ = 0 | |

77th surface:

| | |
|---|---|
| κ = 0 | |
| C₄ = 3.89354 × 10⁻⁹ | C₆ = 1.75637 × 10⁻¹³ |
| C₈ = −6.60208 × 10⁻¹⁷ | C₁₀ = −1.64576 × 10⁻²² |
| C₁₂ = 1.38560 × 10⁻²⁵ | C₁₄ = −2.25476 × 10⁻³⁰ |
| C₁₆ = −7.93455 × 10⁻³⁵ | C₁₈ = 1.83564 × 10⁻³⁹ |
| C₂₀ = 0 | |

80th surface:

| | |
|---|---|
| κ = 0 | |
| C₄ = −1.10257 × 10⁻⁸ | C₆ = −2.49708 × 10⁻¹⁴ |
| C₈ = −2.18114 × 10⁻¹⁷ | C₁₀ = −9.63217 × 10⁻²³ |
| C₁₂ = 6.03363 × 10⁻²⁶ | C₁₄ = −2.27688 × 10⁻³⁰ |
| C₁₆ = 3.64117 × 10⁻³⁵ | C₁₈ = −2.15444 × 10⁻⁴⁰ |
| C₂₀ = 0 | |

81st surface:

| | |
|---|---|
| κ = 0 | |
| C₄ = 2.43343 × 10⁻⁸ | C₆ = −1.74414 × 10⁻¹³ |
| C₈ = −2.30411 × 10⁻¹⁹ | C₁₀ = −1.14245 × 10⁻²² |
| C₁₂ = 1.07584 × 10⁻²⁶ | C₁₄ = −4.57737 × 10⁻³¹ |
| C₁₆ = 9.71876 × 10⁻³⁶ | C₁₈ = −1.26377 × 10⁻⁴⁰ |
| C₂₀ = 0 | |

89th surface:

| | |
|---|---|
| κ = 0 | |
| C₄ = 3.76281 × 10⁻⁸ | C₆ = −2.28156 × 10⁻¹² |
| C₈ = 1.92084 × 10⁻¹⁶ | C₁₀ = −9.89908 × 10⁻²¹ |
| C₁₂ = 2.81981 × 10⁻²⁵ | C₁₄ = −4.25238 × 10⁻³⁰ |
| C₁₆ = 2.66740 × 10⁻³⁵ | C₁₈ = 0 |
| C₂₀ = 0 | |

91st surface:

| | |
|---|---|
| κ = 0 | |
| C₄ = −8.65513 × 10⁻⁹ | C₆ = −4.31357 × 10⁻¹² |
| C₈ = −1.72066 × 10⁻¹⁶ | C₁₀ = 7.12083 × 10⁻²⁰ |
| C₁₂ = −9.72308 × 10⁻²⁴ | C₁₄ = 6.27371 × 10⁻²⁸ |
| C₁₆ = −1.88783 × 10⁻³² | C₁₈ = 0 |
| C₂₀ = 0 | |

(Values Corresponding to Condition Expressions)

D1 = D2 = 1028.2 mm
D3 = D4 = 1008.2 mm
β3 = β6 = 1.19
β23 = β56 = 1.16
D13 = D24 = 1358.6 mm
S = 450 mm
LO1 = LO2 = 3.8 mm
B = 15.3 mm
A1 = A2 = 63.55° (rays assuming minimum)
A3 = A4 = 26.35° (rays assuming minimum)
A1 = A2 = 46.44° (rays assuming maximum)
A3 = A4 = 46.00° (rays assuming maximum)
(1) LO1/B = 0.248
(2) LO2/B = 0.248
(7) (A1 + A3) = 89.91 (rays assuming minimum)
(8) (A2 + A4) = 89.91 (rays assuming minimum)
(7) (A1 + A3) = 92.44 (rays assuming maximum)
(8) (A2 + A4) = 92.44 (rays assuming maximum)
(12) D13/S = 3.019
(13) D24/S = 3.019

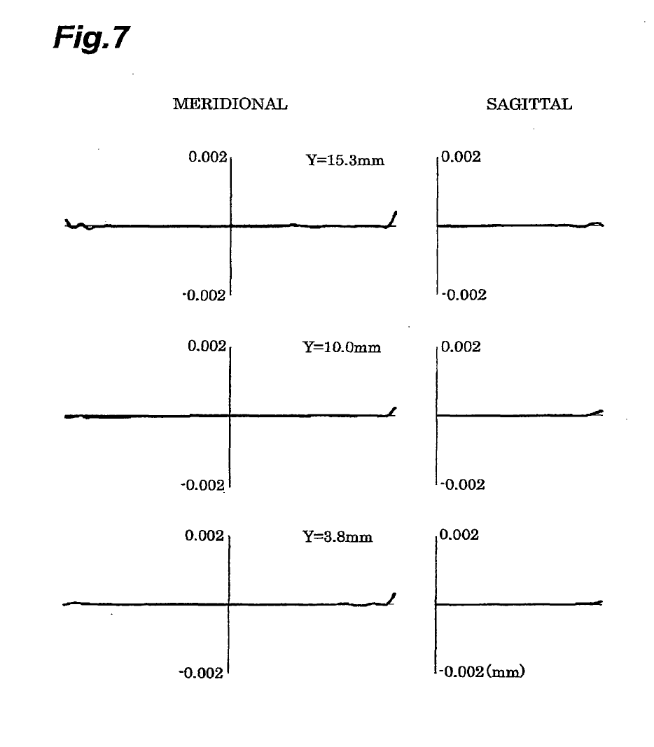

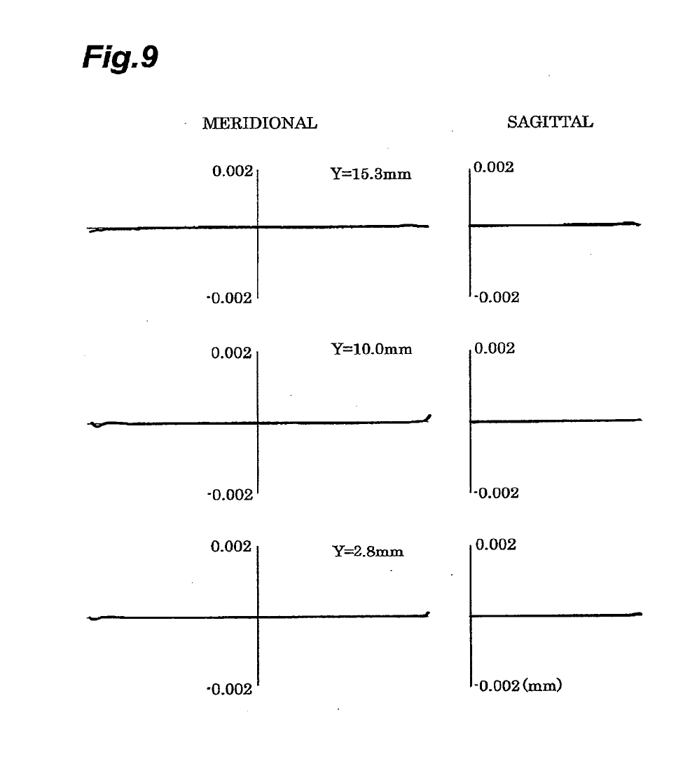

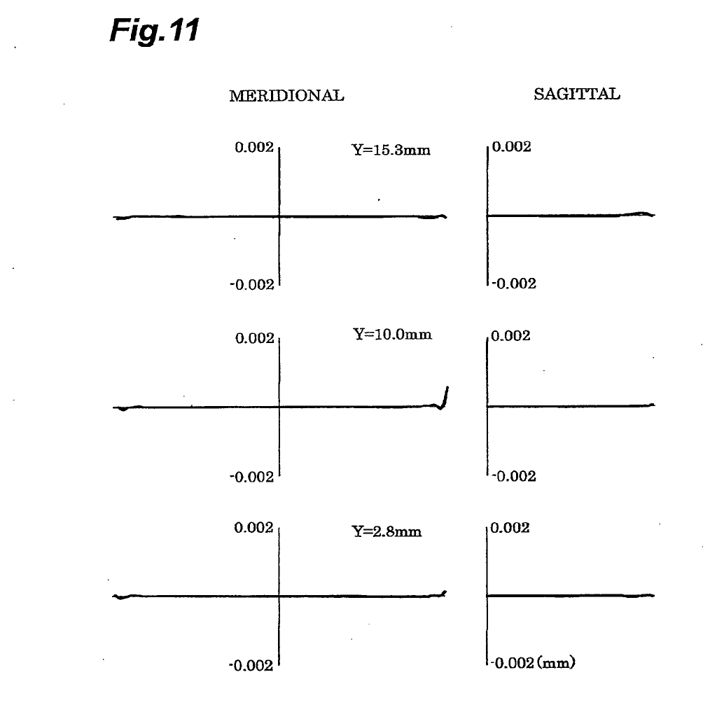

FIG. 7 is a drawing showing transverse aberrations in the first example. In aberration diagrams, Y represents the image height. The same notation in FIG. 7 also applies to FIG. 9 and FIG. 11 below. It is apparent from the aberration diagrams in FIG. 7 that the projection optical system of the first example is well corrected for the aberrations for the excimer laser light at the wavelength of 193.306 nm, while ensuring the very large image-side numerical aperture (NA=1.40) and relatively large still exposure region ER (26 mm×15.6 mm) including the pair of still exposure regions ERa, ERb (26 mm×4 mm).

### Second Example

FIG. 8 is a drawing showing a lens configuration of the projection optical system according to the second example of the embodiment. With reference to FIG. 8, in the projection optical system PL of the second example the first imaging optical system G1 is composed of twelve lenses L11-L112 arranged in order from the entrance side of light along the optical axis AX1 extending in the Z-direction. The second imaging optical system G2 is composed of one positive lens L21, two negative lenses L22 and L23, and a concave reflecting mirror CM2 arranged in order from the entrance side of light along the optical axis AX2 lying on the same straight line as the optical axis AX1. The third imaging optical system G3 is composed of ten lenses L31-L310 arranged in order from the entrance side of light along the optical axis AX3 extending in the X-direction.

The fourth imaging optical system G4, fifth imaging optical system G5, and sixth imaging optical system G6 have the same configurations as the first imaging optical system G1, second imaging optical system G2, and third imaging optical system G3, respectively, and therefore the description of the configurations is omitted herein. The seventh imaging optical system G7 is composed of fifteen lenses L71-L715 arranged in order from the entrance side of light along the optical axis AX7 extending in the Z-direction. The planoconvex lens L715 arranged nearest to the wafer in the seventh imaging optical system G7 constitutes a boundary lens Lb. In the second example, as in the first example, there is a paraxial pupil position inside the lens L712 and an aperture stop AS is arranged at this paraxial pupil position.

In the second example, as in the first example, the optical path between the boundary lens Lb and the wafer W is filled with pure water (Lm) having the refractive index of 1.435876 for the ArF excimer laser light (wavelength λ=193.306 nm) of used light. All optically transparent members are made of silica glass having the refractive index of 1.5603261 for the used light. Table (2) below provides values of specifications of the projection optical system PL according to the second example.

TABLE (2)
(Main Specs)

λ = 193.306 nm
β = ¼
NA = 1.35
B = 15.3 mm
LO1 = LO2 = 2.8 mm
LXa = LXb = 26 mm
LYa = LYb = 5 mm

(Specs of Optical Members)

| | | | | Optical |
|---|---|---|---|---|
| Surface No. | r | d | n | Member |
| | (mask surface) | 68.06061 | | |
| 1 | −586.07580 | 20.20434 | 1.5603261 | L11(L41) |
| 2 | −230.61494 | 107.59457 | | |
| 3 | −242.18447 | 74.47034 | 1.5603261 | L12(L42) |
| 4 | −211.26515 | 23.77336 | | |
| 5 | 207.49610 | 61.57929 | 1.5603261 | L13(L43) |
| 6 | −8412.54586 | 2.54546 | | |
| 7 | 299.13005 | 17.89026 | 1.5603261 | L14(L44) |
| 8 | 397.83466 | 2.90753 | | |
| 9 | 131.08330 | 36.41651 | 1.5603261 | L15(L45) |
| 10 | 203.23998 | 78.67572 | | |
| 11 | −233.01106 | 9.16442 | 1.5603261 | L16(L46) |
| 12 | 173.12941 | 21.66873 | | |
| 13 | −217.24440 | 25.03962 | 1.5603261 | L17(L47) |
| 14 | −103.58397 | 10.27527 | | |
| 15 | −156.73082 | 12.19868 | 1.5603261 | L18(L48) |
| 16 | −451.14666 | 29.47704 | | |
| 17* | −209.61197 | 58.53488 | 1.5603261 | L19(L49) |
| 18 | −657.02163 | 1.00000 | | |
| 19 | −1084.50282 | 76.00000 | 1.5603261 | L110(L410) |
| 20 | −151.07953 | 1.00000 | | |
| 21 | 414.09389 | 60.69805 | 1.5603261 | L111(L411) |
| 22 | −549.86813 | 1.00000 | | |
| 23 | 487.71156 | 25.00000 | 1.5603261 | L112(L412) |
| 24* | 947.46317 | 100.00000 | | |
| 25 | ∞ | 25.00000 | | virtual surface |
| 26 | ∞ | 1.00000 | | virtual surface |
| 27 | 160.46928 | 69.97494 | 1.5603261 | L21(L51) |
| 28 | 843.99607 | 137.58178 | | |
| 29 | −111.60543 | 9.00000 | 1.5603261 | L22(L52) |
| 30 | 19124.96743 | 73.67050 | | |
| 31 | −98.17593 | 18.00000 | 1.5603261 | L23(L53) |
| 32 | −209.71239 | 26.10584 | | |
| 33 | −154.71296 | −26.10584 | | CM2(CM5) |
| 34 | −209.71239 | −18.00000 | 1.5603261 | L23(L53) |
| 35 | −98.17593 | −73.67050 | | |
| 36 | 19124.96743 | −9.00000 | 1.5603261 | L22(L52) |
| 37 | −111.60543 | −137.58178 | | |
| 38 | 843.99607 | −69.97494 | 1.5603261 | L21(L51) |
| 39 | 160.46928 | −1.00000 | | |
| 40 | ∞ | −25.00000 | | virtual surface |
| 41 | ∞ | −189.39944 | | R23(R56) |
| 42 | −532.97111 | −40.22107 | 1.5603261 | L31(L61) |
| 43 | 622.49059 | −1.00000 | | |
| 44 | −421.23764 | −24.40755 | 1.5603261 | L32(L62) |
| 45 | −1272.87198 | −1.00000 | | |
| 46 | −229.48600 | −19.17842 | 1.5603261 | L33(L63) |
| 47 | −269.28627 | −122.85175 | | |
| 48 | −645.80191 | −74.21251 | 1.5603261 | L34(L64) |
| 49 | 635.78890 | −37.24572 | | |
| 50 | −150.61476 | −25.64829 | 1.5603261 | L35(L65) |
| 51 | −443.47226 | −24.30180 | | |
| 52 | 195.09674 | −46.88195 | 1.5603261 | L36(L66) |
| 53 | −162.86268 | −13.63274 | | |
| 54 | −370.50911 | −32.47484 | 1.5603261 | L37(L67) |
| 55 | 251.33855 | −103.13304 | | |
| 56* | 575.89090 | −54.22594 | 1.5603261 | L38(L68) |
| 57 | 193.02587 | −89.82690 | | |
| 58 | 362.81083 | −47.94952 | 1.5603261 | L39(L69) |
| 59 | 209.74590 | −18.32614 | | |
| 60 | 1220.18658 | −76.00000 | 1.5603261 | L310(L610) |
| 61 | 323.72836 | −128.59060 | | |
| 62 | ∞ | −66.50000 | | R37(R67) |
| 63 | 144.32133 | −52.63909 | 1.5603261 | L71 |
| 64 | 171.85869 | −1.00000 | | |
| 65 | −284.71313 | −41.71221 | 1.5603261 | L72 |
| 66 | 624.37054 | −1.00000 | | |
| 67 | −165.85811 | −56.22944 | 1.5603261 | L73 |
| 68 | −317.65007 | −14.10507 | | |
| 69 | −43303.28155 | −9.00000 | 1.5603261 | L74 |
| 70 | −120.72404 | −58.60639 | | |
| 71 | 126.46159 | −9.00000 | 1.5603261 | L75 |
| 72* | −546.08105 | −26.35345 | | |
| 73* | 351.10634 | −39.68597 | 1.5603261 | L76 |
| 74 | 147.99829 | −1.00000 | | |
| 75 | −222.56532 | −63.69401 | 1.5603261 | L77 |
| 76* | −3333.33333 | −26.19524 | | |
| 77* | 1483.54746 | −64.78136 | 1.5603261 | L78 |
| 78 | 204.53525 | −1.00000 | | |
| 79 | 264.62152 | −20.00000 | 1.5603261 | L79 |
| 80* | −3333.33333 | −41.27541 | | |
| 81* | 434.62199 | −46.00882 | 1.5603261 | L710 |
| 82 | 368.94779 | −1.00000 | | |
| 83 | −2097.98781 | −70.30535 | 1.5603261 | L711 |
| 84 | 514.62050 | −14.00000 | | |
| 85 | ∞ | 13.00000 | | AS |
| 86 | −304.02823 | −57.71913 | 1.5603261 | L712 |
| 87 | −103596.14860 | −1.00000 | | |
| 88 | −190.85747 | −69.41405 | 1.5603261 | L713 |
| 89* | −984.28103 | −1.00000 | | |
| 90 | −108.98885 | −50.25913 | 1.5603261 | L714 |
| 91* | −306.74470 | −1.00000 | | |
| 92 | −67.43913 | −49.90000 | 1.5603261 | L715:Lb |
| 93 | ∞ | −3.00000 | 1.435876 | Lm |
| | (wafer surface) | | | |

(aspheric data)
17th surface:

| | |
|---|---|
| κ = 0 | |
| C₄ = −9.56145 × 10⁻⁹ | C₆ = −1.57185 × 10⁻¹² |
| C₈ = −9.99870 × 10⁻¹⁷ | C₁₀ = 2.34259 × 10⁻²¹ |
| C₁₂ = −3.66502 × 10⁻²⁴ | C₁₄ = 9.03279 × 10⁻²⁸ |
| C₁₆ = −1.53772 × 10⁻³¹ | C₁₈ = 1.39045 × 10⁻³⁵ |
| C₂₀ = −5.82675 × 10⁻⁴⁰ | |

24th surface:

| | |
|---|---|
| κ = 0 | |
| C₄ = 1.41766 × 10⁻⁸ | C₆ = 4.92551 × 10⁻¹⁴ |
| C₈ = 2.52764 × 10⁻¹⁸ | C₁₀ = −1.83214 × 10⁻²² |
| C₁₂ = 4.78600 × 10⁻²⁶ | C₁₄ = −6.45055 × 10⁻³⁰ |
| C₁₆ = 5.33388 × 10⁻³⁴ | C₁₈ = −2.46004 × 10⁻³⁸ |
| C₂₀ = 4.91635 × 10⁻⁴³ | |

56th surface:

| | |
|---|---|
| κ = 0 | |
| C₄ = 2.91460 × 10⁻⁸ | C₆ = 2.96485 × 10⁻¹⁴ |
| C₈ = 7.80884 × 10⁻¹⁸ | C₁₀ = −1.82018 × 10⁻²¹ |
| C₁₂ = 3.97048 × 10⁻²⁵ | C₁₄ = −4.39778 × 10⁻²⁹ |
| C₁₆ = 3.15627 × 10⁻³³ | C₁₈ = −1.26256 × 10⁻³⁷ |
| C₂₀ = 2.30521 × 10⁻⁴² | |

72nd surface:

| | |
|---|---|
| κ = 0 | |
| C₄ = −4.44233 × 10⁻⁸ | C₆ = 1.32427 × 10⁻¹² |
| C₈ = −7.36896 × 10⁻¹⁷ | C₁₀ = −1.13507 × 10⁻²⁰ |
| C₁₂ = 6.61590 × 10⁻²⁵ | C₁₄ = 1.12866 × 10⁻²⁹ |
| C₁₆ = 1.92627 × 10⁻³³ | C₁₈ = −1.35231 × 10⁻³⁷ |
| C₂₀ = 0 | |

73rd surface:

| | |
|---|---|
| κ = 0 | |
| C₄ = 2.98792 × 10⁻⁹ | C₆ = −1.22687 × 10⁻¹² |
| C₈ = −1.10963 × 10⁻¹⁶ | C₁₀ = −2.74018 × 10⁻²¹ |
| C₁₂ = −9.02362 × 10⁻²⁵ | C₁₄ = 1.72989 × 10⁻²⁸ |
| C₁₆ = −2.08935 × 10⁻³² | C₁₈ = 1.43649 × 10⁻³⁶ |
| C₂₀ = −3.56165 × 10⁻⁴¹ | |

76th surface:

| | |
|---|---|
| κ = 0 | |
| C₄ = 4.35491 × 10⁻⁹ | C₆ = −6.25188 × 10⁻¹³ |
| C₈ = −5.73946 × 10⁻¹⁷ | C₁₀ = 1.01130 × 10⁻²¹ |
| C₁₂ = 1.32853 × 10⁻²⁵ | C₁₄ = −5.51909 × 10⁻³⁰ |
| C₁₆ = −1.25342 × 10⁻³⁵ | C₁₈ = 2.66388 × 10⁻³⁹ |
| C₂₀ = 0 | |

77th surface:

| | |
|---|---|
| κ = 0 | |
| C₄ = 1.24076 × 10⁻⁸ | C₆ = 4.27672 × 10⁻¹³ |
| C₈ = −4.36725 × 10⁻¹⁷ | C₁₀ = 7.46514 × 10⁻²² |
| C₁₂ = 1.62422 × 10⁻²⁵ | C₁₄ = −3.46915 × 10⁻³⁰ |
| C₁₆ = −2.18464 × 10⁻³⁴ | C₁₈ = 6.58361 × 10⁻³⁹ |
| C₂₀ = 0 | |

80th surface:

| | |
|---|---|
| κ = 0 | |
| C₄ = −2.10612 × 10⁻⁸ | C₆ = −3.29044 × 10⁻¹³ |
| C₈ = −3.22807 × 10⁻¹⁷ | C₁₀ = −1.19075 × 10⁻²² |
| C₁₂ = 6.27225 × 10⁻²⁶ | C₁₄ = −1.94725 × 10⁻³⁰ |
| C₁₆ = 1.01737 × 10⁻³⁴ | C₁₈ = −2.40677 × 10⁻³⁹ |
| C₂₀ = 0 | |

81st surface:

| | |
|---|---|
| κ = 0 | |
| C₄ = 1.34892 × 10⁻⁸ | C₆ = −4.45318 × 10⁻¹³ |
| C₈ = −3.86230 × 10⁻¹⁸ | C₁₀ = −1.37972 × 10⁻²² |
| C₁₂ = 2.51819 × 10⁻²⁷ | C₁₄ = −3.41940 × 10⁻³¹ |
| C₁₆ = 5.07318 × 10⁻³⁶ | C₁₈ = −3.10844 × 10⁻⁴⁰ |
| C₂₀ = 0 | |

89th surface:

| | |
|---|---|
| κ = 0 | |
| C₄ = 2.55387 × 10⁻⁸ | C₆ = −2.57930 × 10⁻¹² |
| C₈ = 1.88405 × 10⁻¹⁶ | C₁₀ = −9.46669 × 10⁻²¹ |
| C₁₂ = 2.98973 × 10⁻²⁵ | C₁₄ = −5.39794 × 10⁻³⁰ |
| C₁₆ = 4.24360 × 10⁻³⁵ | C₁₈ = 0 |
| C₂₀ = 0 | |

91st surface:

| | |
|---|---|
| κ = 0 | |
| C₄ = −6.11181 × 10⁻⁸ | C₆ = −1.72922 × 10⁻¹² |
| C₈ = −3.43795 × 10⁻¹⁶ | C₁₀ = 6.76083 × 10⁻²⁰ |
| C₁₂ = −9.56074 × 10⁻²⁴ | C₁₄ = 6.80986 × 10⁻²⁸ |
| C₁₆ = −2.90856 × 10⁻³² | C₁₈ = 0 |
| C₂₀ = 0 | |

(Values Corresponding to Condition Expressions)

D1 = D2 = 945.4 mm
D3 = D4 = 925.2 mm
β3 = β6 = 1.21
β23 = β56 = 1.29
D13 = D24 = 1170.5 mm
S = 450 mm
LO1 = LO2 = 2.8 mm
B = 15.3 mm
A1 = A2 = 62.92° (rays assuming minimum)
A3 = A4 = 26.95° (rays assuming minimum)
A1 = A2 = 30.21° (rays assuming maximum)
A3 = A4 = 63.79° (rays assuming maximum)
(1) LO1/B = 0.183
(2) LO2/B = 0.183
(7) (A1 + A3) = 89.87 (rays assuming minimum)
(8) (A2 + A4) = 89.87 (rays assuming minimum)
(7) (A1 + A3) = 94.00 (rays assuming maximum)
(8) (A2 + A4) = 94.00 (rays assuming maximum)
(12) D13/S = 2.601
(13) D24/S = 2.601

FIG. 9 is a thawing showing transverse aberrations in the second example. It is apparent from the aberration diagrams in FIG. 9 that the projection optical system of the second example is well corrected for the aberrations for the excimer laser light at the wavelength of 193.306 nm, while ensuring the very large image-side numerical aperture (NA=1.35) and relatively large still exposure region ER (26 mm×15.6 mm) including the pair of still exposure regions ERa, ERb (26 mm×5 mm).

### Third Example

FIG. 10 is a drawing showing a lens configuration of the projection optical system according to the third example of the embodiment. With reference to FIG. 10, in the projection optical system PL of the third example the first imaging optical system G1 is composed of twelve lenses L11-L112 arranged in order from the entrance side of light along the optical axis AX1 extending in the Z-direction. The second imaging optical system G2 is composed of two negative lenses L21 and L22, and a concave reflecting mirror CM2 arranged in order from the entrance side of light along the optical axis AX2 lying on the same straight line as the optical axis AX1. The third imaging optical system G3 is composed of ten lenses L31-L310 arranged in order from the entrance side of light along the optical axis AX3 extending in the X-direction.

The fourth imaging optical system G4, fifth imaging optical system G5, and sixth imaging optical system G6 have the same configurations as the first imaging optical system G1, second imaging optical system G2, and third imaging optical system G3, respectively, and therefore the description of the configurations is omitted herein. The seventh imaging optical system G7 is composed of fifteen lenses L71-L715 arranged in order from the entrance side of light along the optical axis AX7 extending in the Z-direction. The planoconvex lens L715 arranged nearest to the wafer in the seventh imaging optical system G7 constitutes a boundary lens Lb. In the third example, as in the first example and the second example, there is a paraxial pupil position inside the lens L712 and an aperture stop AS is arranged at this paraxial pupil position.

In the third example, as in the first example and the second example, the optical path between the boundary lens Lb and the wafer W is filled with pure water (Lm) having the refractive index of 1.435876 for the ArF excimer laser light (wavelength λ=193.306 nm) of used light. All optically transparent members are made of silica glass having the refractive index of 1.5603261 for the used light. Table (3) below provides values of specifications of the projection optical system PL according to the third example.

TABLE (3)
(Main Specs)

λ = 193.306 nm
β = ¼
NA = 1.35
B = 15.3 mm
LO1 = LO2 = 2.8 mm
LXa = LXb = 26 mm
LYa = LYb = 5 mm

(Specs of Optical Members)

| | | | | Optical |
|---|---|---|---|---|
| Surface No. | r | d | n | Member |
| | (mask surface) | 68.305417 | | |
| 1 | −418.69974 | 20.258719 | 1.5603261 | L11(L41) |
| 2 | −202.12761 | 109.082946 | | |
| 3 | 468.86576 | 43.995889 | 1.5603261 | L12(L42) |
| 4 | −348.58396 | 1.000000 | | |
| 5 | 209.82001 | 35.388927 | 1.5603261 | L13(L43) |
| 6 | 1232.64488 | 1.000000 | | |
| 7 | 162.91710 | 10.738403 | 1.5603261 | L14(L44) |
| 8 | 150.00000 | 62.420165 | | |
| 9 | 93.89563 | 32.197906 | 1.5603261 | L15(L45) |
| 10 | 117.46797 | 22.824902 | | |
| 11 | −228.68609 | 17.713937 | 1.5603261 | L16(L46) |
| 12 | −3841.07700 | 17.473213 | | |
| 13 | −114.86308 | 22.598485 | 1.5603261 | L17(L47) |
| 14 | −90.85055 | 16.126395 | | |
| 15 | −125.56482 | 9.540206 | 1.5603261 | L18(L48) |
| 16 | −1287.20683 | 87.952880 | | |
| 17* | −238.52458 | 60.748800 | 1.5603261 | L19(L49) |
| 18 | −167.54100 | 1.000000 | | |
| 19 | −726.14197 | 52.845620 | 1.5603261 | L110(L410) |
| 20 | −202.08828 | 1.000000 | | |
| 21 | 263.85496 | 44.829956 | 1.5603261 | L111(L411) |
| 22 | −9136.04306 | 1.000000 | | |
| 23 | 234.92083 | 29.180498 | 1.5603261 | L112(L412) |
| 24* | 614.69993 | 100.005766 | | |
| 25 | ∞ | 182.541720 | | virtual surface |
| 26 | −107.69408 | 9.018062 | 1.5603261 | L21(L51) |
| 27 | −634.77519 | 56.779561 | | |
| 28 | −113.16823 | 18.000000 | 1.5603261 | L22(L52) |
| 29 | −227.30779 | 33.135378 | | |
| 30 | −163.37480 | −33.135378 | | CM2(CM5) |
| 31 | −227.30779 | −18.000000 | 1.5603261 | L22(L52) |
| 32 | −113.16823 | −56.779561 | | |
| 33 | −634.77519 | −9.018062 | 1.5603261 | L21(L51) |
| 34 | −107.69408 | −182.541720 | | |
| 35 | ∞ | −189.399444 | | R23(R56) |
| 36 | 1564.92668 | −50.368928 | 1.5603261 | L31(L61) |
| 37 | 268.34811 | −1.000000 | | |
| 38 | 7918.52031 | −28.473308 | 1.5603261 | L32(L62) |
| 39 | 654.73510 | −1.000000 | | |
| 40 | −1839.56946 | −75.716228 | 1.5603261 | L33(L63) |
| 41 | 5979.23492 | −99.700277 | | |
| 42 | −258.08494 | −64.572369 | 1.5603261 | L34(L64) |
| 43 | −3134.42911 | −140.416272 | | |
| 44 | −152.03879 | −28.036965 | 1.5603261 | L35(L65) |
| 45 | −352.24679 | −17.463095 | | |
| 46 | 631.39933 | −48.280275 | 1.5603261 | L36(L66) |
| 47 | −141.34789 | −76.056277 | | |
| 48 | −336.86614 | −75.966104 | 1.5603261 | L37(L67) |
| 49 | −3105.40731 | −64.957316 | | |
| 50* | 708.21028 | −69.672733 | 1.5603261 | L38(L68) |
| 51 | 186.79128 | −14.290084 | | |
| 52 | 233.61816 | −75.970951 | 1.5603261 | L39(L69) |
| 53 | 190.41690 | −5.441923 | | |
| 54 | −8387.96593 | −42.116370 | 1.5603261 | L310(L610) |
| 55 | 347.61300 | −133.910143 | | |
| 56 | ∞ | −66.500000 | | R37(R67) |
| 57 | 148.38791 | −75.986723 | 1.5603261 | L71 |
| 58 | 183.99840 | −1.000000 | | |
| 59 | −266.62689 | −36.724312 | 1.5603261 | L72 |
| 60 | 554.52607 | −1.000000 | | |
| 61 | −151.23538 | −33.481157 | 1.5603261 | L73 |
| 62 | −451.26020 | −12.591952 | | |
| 63 | 1318.56526 | −9.000000 | 1.5603261 | L74 |
| 64 | −112.50842 | −55.191096 | | |
| 65 | 127.08160 | −9.110781 | 1.5603261 | L75 |
| 66* | −434.93767 | −26.663812 | | |
| 67* | 280.93202 | −32.403526 | 1.5603261 | L76 |
| 68 | 166.63855 | −1.000000 | | |
| 69 | −262.40251 | −60.427027 | 1.5603261 | L77 |
| 70* | 1626.04270 | −14.269217 | | |
| 71* | 1261.43173 | −65.194630 | 1.5603261 | L78 |
| 72 | 195.66529 | −1.000000 | | |
| 73 | 225.84163 | −20.000000 | 1.5603261 | L79 |
| 74* | 1501.95254 | −25.281741 | | |
| 75* | 824.45668 | −46.653403 | 1.5603261 | L710 |
| 76 | 297.96105 | −1.000000 | | |
| 77 | 634.46297 | −58.228920 | 1.5603261 | L711 |
| 78 | 325.07548 | −15.000000 | | |
| 79 | ∞ | 14.000000 | | AS |
| 80 | −290.52967 | −59.050911 | 1.5603261 | L712 |
| 81 | −8775.90458 | −1.000000 | | |
| 82 | −175.41392 | −72.464453 | 1.5603261 | L713 |
| 83* | −688.48238 | −1.000000 | | |
| 84 | −113.94730 | −48.105370 | 1.5603261 | L714 |
| 85* | −339.77086 | −1.000000 | | |
| 86 | −68.10513 | −49.900000 | 1.5603261 | L715:Lb |
| 87 | ∞ | −3.000000 | 1.435876 | Lm |
| | (wafer surface) | | | |

(aspheric data)
17th surface:

| | |
|---|---|
| κ = 0 | |
| C₄ = −3.27118 × 10⁻⁹ | C₆ = −1.48666 × 10⁻¹³ |
| C₈ = −6.96468 × 10⁻¹⁸ | C₁₀ = −6.09245 × 10⁻²² |
| C₁₂ = 1.21506 × 10⁻²⁵ | C₁₄ = −1.32987 × 10⁻²⁹ |
| C₁₆ = 7.18321 × 10⁻³⁴ | C₁₈ = −1.76026 × 10⁻³⁸ |
| C₂₀ = 5.10230 × 10⁻⁴⁴ | |

24th surface:

| | |
|---|---|
| κ = 0 | |
| C₄ = 1.29724 × 10⁻⁸ | C₆ = −3.03557 × 10⁻¹⁴ |
| C₈ = 4.76645 × 10⁻¹⁸ | C₁₀ = −7.92360 × 10⁻²² |
| C₁₂ = 1.35265 × 10⁻²⁵ | C₁₄ = −1.41637 × 10⁻²⁹ |
| C₁₆ = 9.07550 × 10⁻³⁴ | C₁₈ = −3.23556 × 10⁻³⁸ |
| C₂₀ = 4.91635 × 10⁻⁴³ | |

50th surface:

| | |
|---|---|
| κ = 0 | |
| C₄ = 4.92318 × 10⁻⁸ | C₆ = 8.09076 × 10⁻¹³ |
| C₈ = 2.08842 × 10⁻¹⁷ | C₁₀ = −6.06320 × 10⁻²² |
| C₁₂ = 3.73303 × 10⁻²⁵ | C₁₄ = −4.54970 × 10⁻²⁹ |
| C₁₆ = 4.13592 × 10⁻³³ | C₁₈ = −2.00047 × 10⁻³⁷ |
| C₂₀ = 4.59787 × 10⁻⁴² | |

66th surface:

| | |
|---|---|
| κ = 0 | |
| C₄ = −2.77775 × 10⁻⁹ | C₆ = 3.20301 × 10⁻¹² |
| C₈ = −3.76509 × 10⁻¹⁷ | C₁₀ = −8.37032 × 10⁻²³ |
| C₁₂ = −3.59102 × 10⁻²⁴ | C₁₄ = 5.40058 × 10⁻²⁸ |
| C₁₆ = −4.31608 × 10⁻³² | C₁₈ = 1.05721 × 10⁻³⁶ |
| C₂₀ = 0 | |

67th surface:

| | |
|---|---|
| κ = 0 | |
| C₄ = 3.14482 × 10⁻⁸ | C₆ = 7.71867 × 10⁻¹³ |
| C₈ = 6.40888 × 10⁻¹⁷ | C₁₀ = 1.32070 × 10⁻²⁰ |
| C₁₂ = −4.36601 × 10⁻²⁴ | C₁₄ = 1.02285 × 10⁻²⁷ |
| C₁₆ = −1.64993 × 10⁻³¹ | C₁₈ = 1.47404 × 10⁻³⁵ |
| C₂₀ = −6.16760 × 10⁻⁴⁰ | |

70th surface:

| | |
|---|---|
| κ = 0 | |
| C₄ = 1.79654 × 10⁻⁸ | C₆ = −2.36256 × 10⁻¹³ |
| C₈ = −6.31736 × 10⁻¹⁷ | C₁₀ = 2.83381 × 10⁻²² |
| C₁₂ = 1.37109 × 10⁻²⁵ | C₁₄ = −1.95959 × 10⁻³⁰ |
| C₁₆ = −2.30213 × 10⁻³⁴ | C₁₈ = 7.49611 × 10⁻³⁹ |
| C₂₀ = 0 | |

71st surface:

| | |
|---|---|
| κ = 0 | |
| C₄ = 2.06006 × 10⁻⁸ | C₆ = 1.05320 × 10⁻¹² |
| C₈ = −5.87237 × 10⁻¹⁷ | C₁₀ = 7.52885 × 10⁻²² |
| C₁₂ = 2.17202 × 10⁻²⁵ | C₁₄ = −7.31267 × 10⁻³⁰ |
| C₁₆ = −1.62507 × 10⁻³⁴ | C₁₈ = 8.09985 × 10⁻³⁹ |
| C₂₀ = 0 | |

74th surface:

| | |
|---|---|
| κ = 0 | |
| C₄ = −2.50949 × 10⁻⁸ | C₆ = −1.87366 × 10⁻¹³ |
| C₈ = −2.37045 × 10⁻¹⁷ | C₁₀ = 1.36425 × 10⁻²² |
| C₁₂ = 6.09018 × 10⁻²⁶ | C₁₄ = −6.84000 × 10⁻³¹ |
| C₁₆ = −4.45663 × 10⁻³⁵ | C₁₈ = 8.01917 × 10⁻⁴⁰ |
| C₂₀ = 0 | |

75th surface:

| | |
|---|---|
| κ = 0 | |
| C₄ = 2.00988 × 10⁻⁸ | C₆ = −5.00357 × 10⁻¹³ |
| C₈ = −6.69661 × 10⁻¹⁸ | C₁₀ = −9.58868 × 10⁻²⁴ |
| C₁₂ = 8.55155 × 10⁻²⁷ | C₁₄ = −4.29504 × 10⁻³¹ |
| C₁₆ = 4.74566 × 10⁻³⁶ | C₁₈ = 5.01717 × 10⁻⁴¹ |
| C₂₀ = 0 | |

83rd surface:

| | |
|---|---|
| κ = 0 | |
| C₄ = 2.53940 × 10⁻⁸ | C₆ = −2.51880 × 10⁻¹² |
| C₈ = 1.81244 × 10⁻¹⁶ | C₁₀ = −9.24162 × 10⁻²¹ |
| C₁₂ = 2.97860 × 10⁻²⁵ | C₁₄ = −5.47930 × 10⁻³⁰ |
| C₁₆ = 4.35598 × 10⁻³⁵ | C₁₈ = 0 |
| C₂₀ = 0 | |

85th surface:

| | |
|---|---|
| κ = 0 | |
| C₄ = −6.70652 × 10⁻⁸ | C₆ = −5.15611 × 10⁻¹³ |
| C₈ = −4.36833 × 10⁻¹⁶ | C₁₀ = 6.73884 × 10⁻²⁰ |
| C₁₂ = −8.11358 × 10⁻²⁴ | C₁₄ = 5.16537 × 10⁻²⁸ |
| C₁₆ = −1.93567 × 10⁻³² | C₁₈ = 0 |
| C₂₀ = 0 | |

(Values Corresponding to Condition Expressions)

D1 = D2 = 889.2 mm
D3 = D4 = 869.2 mm
β3 = β6 = 1.38
β23 = β56 = 1.44
D13 = D24 = 1302.8 mm
S = 450 mm
LO1 = LO2 = 2.8 mm
B = 15.3 mm
A1 = A2 = 64.31° (rays assuming minimum)
A3 = A4 = 25.89° (rays assuming minimum)
A1 = A2 = 30.41° (rays assuming maximum)
A3 = A4 = 69.50° (rays assuming maximum)
(1) LO1/B = 0.183
(2) LO2/B = 0.183
(7) (A1 + A3) = 90.21 (rays assuming minimum
(8) (A2 + A4) = 90.21 (rays assuming minimum)
(7) (A1 + A3) = 99.91 (rays assuming maximum)
(8) (A2 + A4) = 99.91 (rays assuming maximum)
(12) D13/S = 2.895
(13) D24/S = 2.895

FIG. 11 is a drawing showing transverse aberrations in the third example. It is apparent from the aberration diagrams in FIG. 11 that the projection optical system of the third example is well corrected for the aberrations for the excimer laser light at the wavelength of 193.306 nm, while ensuring the very large image-side numerical aperture (NA=1.35) and relatively large still exposure region ER (26 mm×15.6 mm) including the pair of still exposure regions ERa, ERb (26 mm×5 mm), as in the second example.

As described above, the projection optical system PL of the embodiment is configured so that pure water (Lm) having the large refractive index is interposed in the optical path between the boundary lens Lb and the wafer W, whereby it is able to secure the relatively large effective image region while ensuring the large effective image-side numerical aperture. In each of the examples, specifically, the projection optical system ensures the large image-side numerical aperture of 1.35 or 1.40 for the ArF excimer laser light with the center wavelength of 193.306 nm and secures the pair of rectangular still exposure regions ERa, ERb, for example, it is able to perform double exposure in high resolution of a circuit pattern in a rectangular exposure region of 26 mm×33 mm.

In each of the above examples, the plane reflecting mirror M23 as the third folding member is disposed between the second imaging optical system G2 and the third imaging optical system G3 and the plane reflecting mirror M56 as the fourth folding member is disposed between the fifth imaging optical system G5 and the sixth imaging optical system G6. However, without having to be limited to this, it is also possible to adopt a modification example wherein a plane reflecting mirror M12 as the third folding member is disposed between the first imaging optical system G1 and the second imaging optical system G2 and wherein a plane reflecting mirror M45 as the fourth folding member is disposed between the fourth imaging optical system G4 and the fifth imaging optical system G5, corresponding to each example.

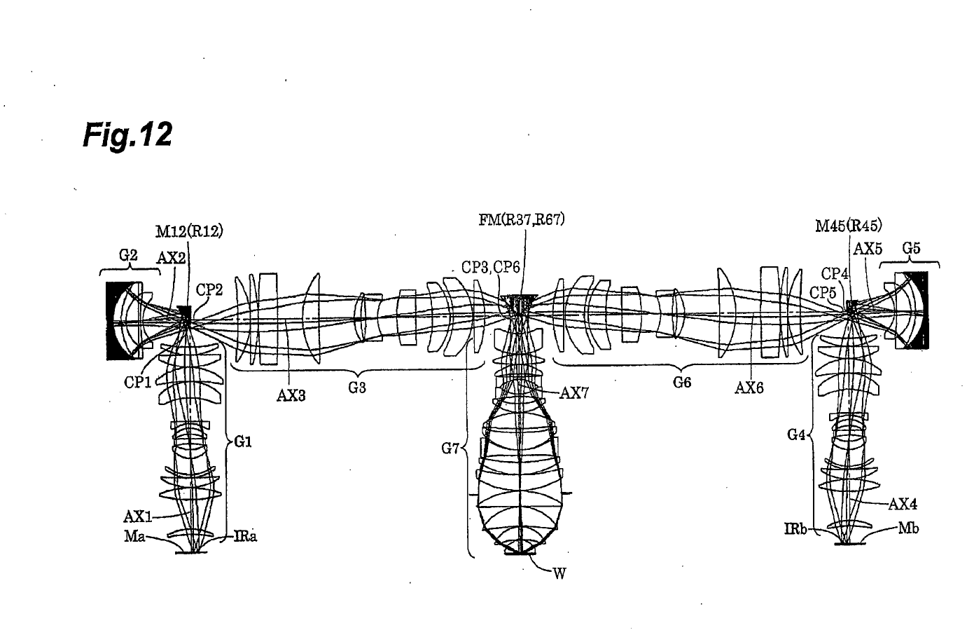

In this case, a reflecting surface R12 (R45) of the plane reflecting mirror M12 (M45) can be arranged at the position of a virtual surface of the twenty fifth surface in each example. FIG. 12 shows a modification example wherein the plane reflecting mirror M12 is disposed between the first imaging optical system G1 and the second imaging optical system G2 and wherein the plane reflecting mirror M45 is disposed between the fourth imaging optical system G4 and the fifth imaging optical system G5, corresponding to the third example.

In each of the above examples the reflecting surface R37 and the reflecting surface R67 are formed in the reflecting mirror FM being a single optical member, but, without having to be limited to this, it is also possible to provide a first folding member with the reflecting surface R37 and a second folding member with the reflecting surface R67 separately.

In each of the above examples, the ridge line formed by the reflecting surface R37 and the reflecting surface R67 of the reflecting mirror FM is located on the point of intersection among the exit-side optical axis AX3 of the third imaging optical system G3, the exit-side optical axis AX6 of the sixth imaging optical system G6, and the entrance-side optical axis AX7 of the seventh imaging optical system G7. However, without having to be limited to this, various forms can be contemplated as to the positional relationship between the ridge line formed by the reflecting surface R37 and the reflecting surface R67, and the optical axes AX3, AX6, AX7 of the imaging optical systems G3, G6, G7.

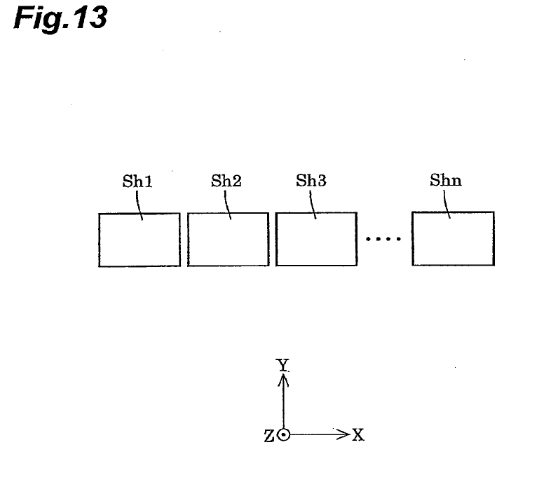

In the foregoing embodiment, while the first mask Ma, the second mask Mb, and the wafer W are synchronously moved along the X-direction relative to the projection optical system PL, one shot area on the wafer W is subjected to scanning exposure with superposition of the pattern of the first mask Ma and the pattern of the second mask Mb to form one composite pattern. However, without having to be limited to this, an exposure apparatus may be configured as shown in FIG. 13: specifically, it is configured to repeat by a required number of times (n times) an operation of scanning exposure of the pattern of the mask Ma in a first shot area Sh1 on the wafer W, an operation of scanning exposure of the pattern of the mask Mb in a second shot area Sh2 adjacent in the scanning movement direction (e.g., the +X-direction) to the first shot area Sh1, and an operation of scanning exposure of the pattern of the mask Ma in a third shot area Sh3 adjacent in the scanning movement direction to the second shot area Sh2, whereby scanning exposures in n shot areas Sh1-SHn aligned in the scanning direction can be continuously performed by simply moving the wafer W along the scanning direction (X-direction), without need for performing two-dimensional step movement of the wafer W.

In this exposure sequence, the aperture of the mask blind MBb of the illumination system ILb is closed during the scanning exposure of the pattern of the mask Ma in the first shot area Sh1, and the mask stage MSb stands by at a start position of scanning exposure in the next second shot area Sh2. Then the aperture of the mask blind MBa of the illumination system ILa is closed during the scanning exposure of the pattern of the mask Mb in the second shot area Sh2, and the mask stage MSa returns from an end position of the scanning exposure in the first shot area Sh1 to a start position of the scanning exposure in the next third shot area Sh3. Thereafter, the aperture of the mask blind MBb of the illumination system ILb is closed during the scanning exposure of the pattern of the mask Ma in the third shot area Sh3, and the mask stage MSb returns from an end position of the scanning exposure in the second shot area Sh2 to a start position of scanning exposure in the next fourth shot area Sh4.

In the foregoing embodiment, one shot area on the photosensitive substrate is subjected to scanning exposure with superposition of the first pattern and the second pattern to form one composite pattern. However, without having to be limited to this, it is also possible to perform scanning exposure or full-shot exposure of the first pattern in the first shot area on the photosensitive substrate and perform scanning exposure or full-shot exposure of the second pattern in the second shot area on the photosensitive substrate.

In the foregoing embodiment, the first illumination region IRa and the second illumination region IRb of the rectangular shape are formed as centered on the optical axis AXa of the first illumination system ILa and on the optical axis AXb of the second illumination system ILb, respectively. However, without having to be limited to this, various forms can be contemplated as to the contour of the illumination regions IRa, IRb, the positional relation of the illumination regions IRa, IRb relative to the optical axes AXa, AXb, and so on.

Recently, research has been directed toward increase in the size of the photosensitive substrate used in the photolithography process. However, the aforementioned conventional technology had the problem that as the number of shot areas provided on the photosensitive substrate increased in conjunction with increase in the size of the photosensitive substrate, the throughput of the photolithography process reduced in accordance with the increase in the number.

Whereas, since the projection optical system according to the embodiment of the present invention adopts the double-headed basic configuration of the four-fold imaging type as described above, it ensures required levels of image-side numerical aperture and effective image region and is able, for example, to form images of patterns on two object planes spaced from each other, in parallel in a predetermined region on an image plane.

Since the projection optical system according to the embodiment of the present invention adopts the configuration wherein the third surface with a wafer thereon is farther from the projection optical system than the first surface and the second surface with respective masks thereon, a movement space of mask stages holding the masks can be separated from a movement space of a wafer stage holding the wafer.

As a consequence, for example, when the projection optical system of the embodiment of the present invention is applied to the scanning exposure apparatus, two different patterns can be printed as superimposed in one shot area on the photosensitive substrate by a single scan operation.

It is also feasible to continuously perform scanning exposure in a plurality of shot areas aligned in a scanning direction, by simply moving the photosensitive substrate in the scanning direction, without need for performing two-dimensional step movement of the photosensitive substrate. Namely, when the projection optical system according to the embodiment of the present invention is applied to the scanning exposure apparatus, the throughput of scanning exposure is drastically improved and, eventually, devices are manufactured at high throughput.

The embodiment of the present invention relates to a projection optical system used in an exposure apparatus used for manufacturing such devices as semiconductor devices and liquid crystal display devices by photolithography.

For example, the illumination optical systems can be those using the technologies disclosed in U.S. Pat. Published Application No. 2007/0258077, U.S. Pat. Published Application No. 2008/0246932, U.S. Pat. Published Application No. 2009/0086186, U.S. Pat. Published Application No. 2009/0040490, and U.S. Pat. Published Application No. 2009/0135396. It is also possible to apply the so-called polarization illumination method as disclosed in U.S. Pat. Published Application No. 2006/0170901 and U.S. Pat. Published Application No. 2007/0146676.

Teachings of U.S. Pat. Published Application No. 2007/0258077, U.S. Pat. Published Application No. 2008/0246932, U.S. Pat. Published Application No. 2009/0086186, U.S. Pat. Published Application No. 2009/0040490, U.S. Pat. Published Application No. 2009/0135396, U.S. Pat. Published Application No. 2006/0170901 and U.S. Pat. Published Application No. 2007/0146676 are incorporated as references herein.

The foregoing embodiment used the ArF excimer laser light source, but, without having to be limited to this, it is also possible, for example, to use another appropriate light source such as a KrF excimer laser light source or F₂ laser light source. The foregoing embodiment was the application of the embodiment of the present invention to the liquid immersion type projection optical system mounted in the exposure apparatus, but, without having to be limited to this, it is also possible to apply the present invention to any other ordinary liquid immersion type projection optical system. The foregoing embodiment was the application of the embodiment of the present invention to the liquid immersion type projection optical system, but, without having to be limited to this, it is also possible to apply the embodiment of the present invention similarly to a dry type projection optical system in which no liquid immersion region is formed on the image side.

In the aforementioned embodiment, each mask can be replaced with a variable pattern forming device which forms a predetermined pattern on the basis of predetermined electronic data. Use of such a variable pattern forming device can minimize influence on synchronization accuracy even when the pattern surface is arranged vertically. The variable pattern forming device applicable herein can be, for example, a spatial light modulator including a plurality of reflective elements driven based on predetermined electronic data. The exposure apparatus with the spatial light modulator is disclosed, for example, in Japanese Patent Application Laid-open No. 2004-304135, International Publication WO2006/080285, and U.S. Pat. Published Application No. 2007/0296936 corresponding thereto. Besides the reflective spatial light modulators of the non-emission type as described above, it is also possible to apply a transmissive spatial light modulator or a self-emission type image display device. It is noted that the variable pattern forming device can also be applied to cases where the pattern surface is arranged horizontally.

The exposure apparatus of the foregoing embodiment is manufactured by assembling various sub-systems containing their respective components as set forth in the scope of claims in the present application, so as to maintain predetermined mechanical accuracy, electrical accuracy, and optical accuracy. For ensuring these various accuracies, the following adjustments are carried out before and after the assembling: adjustment for achieving the optical accuracy for various optical systems; adjustment for achieving the mechanical accuracy for various mechanical systems; adjustment for achieving the electrical accuracy for various electrical systems. The assembling blocks from the various sub-systems into the exposure apparatus include mechanical connections, wire connections of electric circuits, pipe connections of pneumatic circuits, etc. between the various sub-systems. It is needless to mention that there are assembling blocks of the individual sub-systems, before the assembling blocks from the various sub-systems into the exposure apparatus. After completion of the assembling blocks from the various sub-systems into the exposure apparatus, overall adjustment is carried out to ensure various accuracies as the entire exposure apparatus. The manufacture of exposure apparatus is desirably performed in a clean room in which the temperature, cleanliness, etc. are controlled.

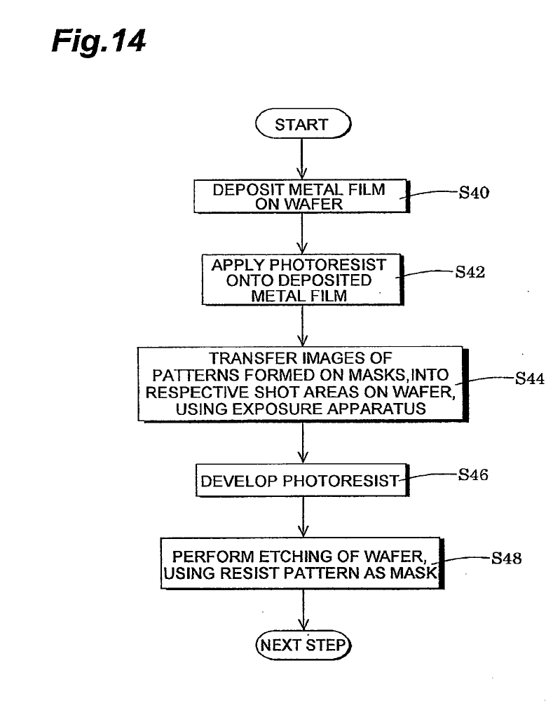

The exposure apparatus of the above-described embodiment can be used to manufacture micro devices (semiconductor devices, imaging devices, liquid crystal display devices, thin-film magnetic heads, etc.) through a process of illuminating masks (reticles) by the illumination devices (illumination block) and exposing a photosensitive substrate with transfer patterns formed on the masks, by the projection optical system (exposure block). The following will describe an example of a method for manufacturing semiconductor devices as micro devices by forming a predetermined circuit pattern on a wafer or the like as a photosensitive substrate by means of the exposure apparatus of the above embodiment, with reference to the flowchart of FIG. 14.

The first block 301 in FIG. 14 is to deposit a metal film on each wafer in one lot. The next block 302 is to apply a photoresist onto the metal film on each wafer in the lot. The subsequent block 303 is to use the exposure apparatus of the above embodiment to sequentially transfer images of patterns on masks into respective shot areas on each wafer in the lot through the projection optical system of the exposure apparatus. The subsequent block 304 is to perform development of the photoresist on each wafer in the lot and the next block 305 is to perform etching using the resist pattern on each wafer in the lot as a mask, and thereby to form circuit patterns corresponding to the patterns on the masks, in the respective shot areas on each wafer.

Thereafter, devices such as semiconductor devices are manufactured through blocks including formation of circuit patterns in upper layers. The above-described semiconductor device manufacturing method permits us to manufacture the semiconductor devices with extremely fine circuit patterns at high throughput. The blocks 301-305 are arranged to perform the respective blocks of deposition of metal on the wafer, application of the resist onto the metal film, exposure, development, and etching, but it is needless to mention that the process may be modified as follows: prior to these blocks, an oxide film of silicon is formed on the wafer, a resist is then applied onto the silicon oxide film, and thereafter the blocks of exposure, development, and etching are carried out.

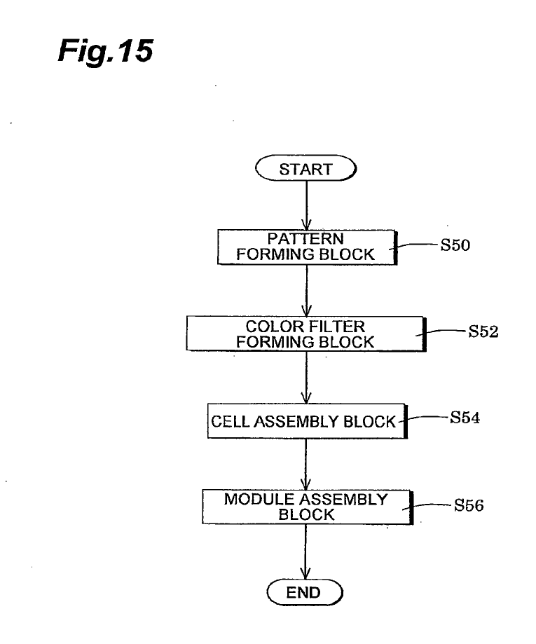

The exposure apparatus of the above embodiment can also be used to manufacture a liquid crystal display device as a micro device by forming predetermined patterns (circuit pattern, electrode pattern, etc.) on plates (glass substrates). An example of a method in this case will be described below with reference to the flowchart of FIG. 15. In FIG. 15, a pattern forming block 401 is to execute the so-called photolithography block of transferring patterns of masks onto a photosensitive substrate (a glass substrate coated with a resist, or the like) by means of the exposure apparatus of the above embodiment. This photolithography block results in forming a predetermined pattern including a large number of electrodes and others on the photosensitive substrate. Thereafter, the exposed substrate is processed through each of blocks including a development block, an etching block, a resist removing block, etc. whereby the predetermined pattern is formed on the substrate, followed by the next color filter forming block 402.

The next color filter forming block 402 is to form a color filter in which a large number of sets of three dots corresponding to R (Red), G (Green), and B (Blue) are arrayed in a matrix pattern or in which sets of filters of three stripes of R, G, and B are arrayed in the horizontal scan line direction. After the color filter forming block 402, a cell assembling block 403 is executed. The cell assembling block 403 is to assemble a liquid crystal panel (liquid crystal cell) using the substrate with the predetermined pattern obtained in the pattern forming block 401, the color filter obtained in the color filter forming block 402, and others.

In the cell assembling block 403, the liquid crystal panel (liquid crystal cell) is manufactured, for example, by pouring a liquid crystal into between the substrate with the predetermined pattern obtained in the pattern forming block 401 and the color filter obtained in the color filter forming block 402. The subsequent module assembling block 404 is to attach various components such as electric circuits and backlights for display operation of the assembled liquid crystal panel (liquid crystal cell) to complete the liquid crystal display device. The above-described manufacturing method of the liquid crystal display device permits us to manufacture the liquid crystal display devices with extremely fine circuit patterns at high throughput.

The invention is not limited to the fore going embodiments but various changes and modifications of its components may be made without departing from the scope of the present invention. Also, the components disclosed in the embodiments may be assembled in any combination for embodying the present invention. For example, some of the components may be omitted from all components disclosed in the embodiments. Further, components in different embodiments may be appropriately combined.

What is claimed is:

1. A projection optical system for forming an image of a first surface and an image of a second surface on a third surface, comprising:
a first imaging optical system disposed in an optical path between the first surface and a first conjugate point optically conjugate with a point which is on the first surface and at which an optical axis intersects with the first surface;
a second imaging optical system disposed in an optical path between the first conjugate point and a second conjugate point optically conjugate with the point which is on the first surface and at which an optical axis intersects with the first surface;
a third imaging optical system disposed in an optical path between the second conjugate point and a third conjugate point optically conjugate with the point which is on the first surface and at which an optical axis intersects with the first surface;
a fourth imaging optical system disposed in an optical path between the second surface and a fourth conjugate point optically conjugate with a point which is on the second surface and at which an optical axis intersects with the second surface;
a fifth imaging optical system disposed in an optical path between the fourth conjugate point and a fifth conjugate point optically conjugate with the point which is on the second surface and at which an optical axis intersects with the second surface;
a sixth imaging optical system disposed in an optical path between the fifth conjugate point and a sixth conjugate point optically conjugate with the point which is on the second surface and at which an optical axis intersects with the second surface;
a seventh imaging optical system disposed in an optical path between the third surface and the third and sixth conjugate points;
a first folding member disposed in an optical path between a surface nearest to the third surface in the third imaging optical system and a surface nearest to the first surface in the seventh imaging optical system and configured to guide light from the third imaging optical system to the seventh imaging optical system; and
a second folding member disposed in an optical path between a surface nearest to the third surface in the sixth imaging optical system and a surface nearest to the second surface in the seventh imaging optical system and configured to guide light from the sixth imaging optical system to the seventh imaging optical system,
wherein every optical element with a power in the seventh imaging optical system is a refracting optical element.

2. The projection optical system according to claim 1, wherein the second imaging optical system and the fifth imaging optical system each include a concave reflecting mirror.

3. The projection optical system according to claim 2, wherein the second imaging optical system and the fifth imaging optical system each include a negative lens.

4. The projection optical system according to claim 1, wherein the first folding member is disposed near the third conjugate point and wherein the second folding member is disposed near the sixth conjugate point.

5. The projection optical system according to claim 1, which has a reduction magnification.

6. The projection optical system according to claim 1, wherein every optical element with a power in the first imaging optical system, the third imaging optical system, the fourth imaging optical system, and the sixth imaging optical system is a refracting optical element.

7. The projection optical system according to claim 1, further comprising: a third folding member disposed in an optical path between the first surface and the first folding member; and a fourth folding member disposed in an optical path between the second surface and the second folding member,
wherein a reflecting surface of the first folding member and a reflecting surface of the third folding member are arranged in parallel with each other and wherein a reflecting surface of the second folding member and a reflecting surface of the fourth folding member are arranged in parallel with each other.

8. The projection optical system according to claim 7,
wherein the third folding member is disposed in an optical path between a surface nearest to the third surface in the second imaging optical system and a surface nearest to the first surface in the third imaging optical system, and
wherein the fourth folding member is disposed in an optical path between a surface nearest to the third surface in the fifth imaging optical system and a surface nearest to the second surface in the sixth imaging optical system.

9. The projection optical system according to claim 8, wherein the third folding member is disposed near the second conjugate point and wherein the fourth folding member is disposed near the fifth conjugate point.

10. The projection optical system according to claim 8,
wherein there is no point optically conjugate with the point on the optical axis in the optical path between the second conjugate point and the third conjugate point and there is no point optically conjugate with the point on the optical axis in the optical path between the fifth conjugate point and the sixth conjugate point, and
wherein an imaging magnification β3 of the third imaging optical system and an imaging magnification β6 of the sixth imaging optical system satisfy the following conditions:
0.5<|β3|<2.0;
0.5<|β6|<2.0.

11. The projection optical system according to claim 8,
wherein the third imaging optical system and the sixth imaging optical system are optical systems telecentric on the entrance side and on the exit side,
wherein an angle between a principal ray from each point in a first effective field region on the first surface upon incidence to the third imaging optical system and the optical axis and an angle between a principal ray from each point in the first effective field region upon exiting from the third imaging optical system and the optical axis both are not more than 5°,
wherein an angle between a principal ray from each point in a second effective field region on the second surface upon incidence to the sixth imaging optical system and the optical axis and an angle between a principal ray from each point in the second effective field region upon exiting from the sixth imaging optical system and the optical axis both are not more than 5°, and
wherein the second imaging optical system and the fifth imaging optical system each include a positive lens.

12. The projection optical system according to claim 7,
wherein the third folding member is disposed in an optical path between a surface nearest to the third surface in the first imaging optical system and a surface nearest to the first surface in the second imaging optical system, and
wherein the fourth folding member is disposed between a surface nearest to the third surface in the fourth imaging optical system and a surface nearest to the second surface in the fifth imaging optical system.

13. The projection optical system according to claim 12, wherein the third folding member is disposed near the first conjugate point and wherein the fourth folding member is disposed near the fourth conjugate point.

14. The projection optical system according to claim 12, wherein there is no point optically conjugate with the point on the optical axis except for the second conjugate point in an optical path between the third conjugate point and the first conjugate point and there is no point optically conjugate with the point on the optical axis except for the fifth conjugate point in an optical path between the sixth conjugate point and the fourth conjugate point, and
wherein an imaging magnification β23 of a composite optical system consisting of the second imaging optical system and the third imaging optical system and an imaging magnification β56 of a composite optical system consisting of the fifth imaging optical system and the sixth imaging optical system satisfy the following conditions:
0.5<|β23|<2.0;
0.5<|β56|<2.0.

15. The projection optical system according to claim 12,
wherein the second imaging optical system and the fifth imaging optical system are optical systems telecentric on the entrance side and the third imaging optical system and the sixth imaging optical system are optical systems telecentric on the exit side,
wherein an angle between a principal ray from each point in a first effective field region on the first surface upon incidence to the second imaging optical system and the optical axis and an angle between a principal ray from each point in the first effective field region upon exiting from the third imaging optical system and the optical axis both are not more than 5°,
wherein an angle between a principal ray from each point in a second effective field region on the second surface upon incidence to the fifth imaging optical system and the optical axis and an angle between a principal ray from each point in the second effective field region upon exiting from the sixth imaging optical system and the optical axis both are not more than 5°, and
wherein the second imaging optical system and the fifth imaging optical system each include a positive lens.

16. The projection optical system according to claim 7, which satisfies the following conditions:
D3≦D1;
D4≦D2;
D1=D2,
where D1 is an axial distance between the third surface and an intersection between the reflecting surface of the first folding member and an optical axis of the seventh imaging optical system,
where D2 is an axial distance between the third surface and an intersection between the reflecting surface of the second folding member and the optical axis of the seventh imaging optical system,
where D3 is an axial distance between the first surface and an intersection between the reflecting surface of the third folding member and an optical axis of the first imaging optical system, and
where D4 is an axial distance between the second surface and an intersection between the reflecting surface of the fourth folding member and an optical axis of the fourth imaging optical system.

17. The projection optical system according to claim 1, wherein a direction of principal rays emitted from the first surface and the second surface is opposite to a direction of principal rays incident to the third surface.

18. The projection optical system according to claim 1, wherein an optical system from the first surface to the first folding member and an optical system from the second surface to the second folding member have the same configuration.

19. The projection optical system according to claim 7, which is a projection optical system to be used in an exposure apparatus for transferring a predetermined pattern set on at least one of the first surface and the second surface, to a photosensitive substrate set on the third surface,
the projection optical system satisfying the following conditions:
2.2<D13/S<5.0;
2.2<D24/S<5.0,
where D13 is a distance along an optical axis of the third imaging optical system between an intersection between the reflecting surface of the first folding member and an optical axis of the seventh imaging optical system and an intersection between the reflecting surface of the third folding member and an optical axis of the first imaging optical system, D24 is a distance along an optical axis of the sixth imaging optical system between an intersection between the reflecting surface of the second folding member and the optical axis of the seventh imaging optical system and an intersection between the reflecting surface of the fourth folding member and an optical axis of the fourth imaging optical system, and S is a maximum diameter of a circle circumscribed to the photosensitive substrate.

20. The projection optical system according to claim 1, which has a first effective field region excluding an optical axis of the first imaging optical system on the first surface, and a second effective field region excluding an optical axis of the fourth imaging optical system on the second surface,
the projection optical system satisfying the following conditions:
0.05<LO1/B<0.4;
0.05<LO2/B<0.4,
where LO1 is a distance between an optical axis of the seventh imaging optical system and a first effective image region formed on the third surface corresponding to the first effective field region, LO2 is a distance between the optical axis of the seventh imaging optical system and a second effective image region formed on the third surface corresponding to the second effective field region, and B is a maximum image height on the third surface.

21. The projection optical system according to claim 1, wherein the first folding member and the second folding member are integrally configured, and wherein a ridge line formed by a reflecting surface of the first folding member and a reflecting surface of the second folding member is located on a point of intersection among an optical axis of the third imaging optical system, an optical axis of the sixth imaging optical system, and an optical axis of the seventh imaging optical system.

22. The projection optical system according to claim 7, wherein the reflecting surface of the first folding member and the reflecting surface of the second folding member are arranged at 45° relative to an optical axis of the seventh imaging optical system, wherein the reflecting surface of the third folding member is arranged at 45° relative to an optical axis of the first imaging optical system, and wherein the reflecting surface of the fourth folding member is arranged at 45° relative to an optical axis of the fourth imaging optical system,
the projection optical system satisfying the following conditions:
70°<(A1+A3)<110°;
70°<(A2+A4)<110°,
where A3 is an angle of incidence at which a ray emitted from a first effective field region on the first surface is incident to the reflecting surface of the third folding member, A1 is an angle of incidence at which the same ray is incident to the reflecting surface of the first folding member, A4 is an angle of incidence at which a ray emitted from a second effective field region on the second surface is incident to the reflecting surface of the fourth folding member, and A2 is an angle of incidence at which the same ray is incident to the reflecting surface of the second folding member.

23. The projection optical system according to claim 1, which is used in a state in which an optical path between the projection optical system and the third surface is filled with a liquid.

24. The projection optical system according to claim 1, wherein the first surface and the second surface are located on an identical plane.

25. The projection optical system according to claim 1, wherein the first surface, the second surface, and the third surface extend horizontally, and wherein the third surface is located below the first surface and the second surface.

26. A projection optical system for forming an image of a first surface and an image of a second surface on a third surface, which is one to be used in an exposure apparatus for transferring a predetermined pattern set on at least one of the first surface and the second surface, to a photosensitive substrate set on the third surface, the projection optical system comprising:
a first optical unit which guides light from the first surface to a path combining device;
a second optical unit which guides light from the second surface to the path combining device; and
a third optical unit which forms the image of the first surface on the third surface, based on the light from the first optical unit having traveled via the path combining device, and which forms the image of the second surface on the third surface, based on the light from the second optical unit having traveled via the path combining device,
wherein the first surface, the second surface, and the third surface extend horizontally in a space below the projection optical system, and
wherein the third surface is located below the first surface and the second surface.

27. The projection optical system according to claim 26,
wherein the first optical unit comprises: a first imaging optical system disposed in an optical path between the first surface and a first conjugate point optically conjugate with a point which is on the first surface and at which an optical axis intersects with the first surface; a second imaging optical system disposed in an optical path between the first conjugate point and a second conjugate point optically conjugate with the point which is on the first surface and at which an optical axis intersects with the first surface; and a third imaging optical system disposed in an optical path between the second conjugate point and a third conjugate point optically conjugate with the point which is on the first surface and at which an optical axis intersects with the first surface,
wherein the second optical unit comprises: a fourth imaging optical system disposed in an optical path between the second surface and a fourth conjugate point optically conjugate with a point which is on the second surface and at which an optical axis intersects with the second surface; a fifth imaging optical system disposed in an optical path between the fourth conjugate point and a fifth conjugate point optically conjugate with the point which is on the second surface and at which an optical axis intersects with the second surface; and a sixth imaging optical system disposed in an optical path between the fifth conjugate point and a sixth conjugate point optically conjugate with the point which is on the second surface and at which an optical axis intersects with the second surface,
wherein the third optical unit comprises a seventh imaging optical system disposed in an optical path between the third surface and the third and sixth conjugate points, and
wherein the path combining device comprises: a first folding member disposed in an optical path between a surface nearest to the third surface in the third imaging optical system and a surface nearest to the first surface in the seventh imaging optical system and configured to guide light from the third imaging optical system to the seventh imaging optical system; and a second folding member disposed in an optical path between a surface nearest to the third surface in the sixth imaging optical system and a surface nearest to the second surface in the seventh imaging optical system and configured to guide light from the sixth imaging optical system to the seventh imaging optical system.

28. An exposure apparatus comprising the projection optical system as set forth in claim 1, for, based on light from a predetermined pattern set on at least one of the first surface and the second surface, projecting the predetermined pattern onto a photosensitive substrate set on the third surface.

29. The exposure apparatus according to claim 28, which moves the predetermined pattern and the photosensitive substrate relative to the projection optical system to project the predetermined pattern onto the photosensitive substrate to effect exposure thereof.

30. A device manufacturing method comprising:
effecting the exposure of the predetermined pattern on the photosensitive substrate, using the exposure apparatus as set forth in claim 28;
developing the photosensitive substrate on which the predetermined pattern has been transferred, to form a mask layer in a shape corresponding to the predetermined pattern on a surface of the photosensitive substrate; and
processing the surface of the photosensitive substrate through the mask layer.

31. An exposure apparatus comprising the projection optical system as set forth in claim 26, for, based on light from a predetermined pattern set on at least one of the first surface and the second surface, projecting the predetermined pattern onto a photosensitive substrate set on the third surface.

32. The exposure apparatus according to claim 31, which moves the predetermined pattern and the photosensitive substrate relative to the projection optical system to project the predetermined pattern onto the photosensitive substrate to effect exposure thereof.

33. A device manufacturing method comprising:
effecting the exposure of the predetermined pattern on the photosensitive substrate, using the exposure apparatus as set forth in claim 31;
developing the photosensitive substrate on which the predetermined pattern has been transferred, to form a mask layer in a shape corresponding to the predetermined pattern on a surface of the photosensitive substrate; and
processing the surface of the photosensitive substrate through the mask layer.

34. An exposure apparatus comprising a projection optical system for forming an image of a first surface and an image of a second surface on a third surface, which is for transferring a predetermined pattern set on at least one of the first surface and the second surface, to a photosensitive substrate set on the third surface, the exposure apparatus comprising:
a first illumination unit which is located below the first surface and which provides a first illumination light with the first surface,
a second illumination unit which is located below the second surface and which provides a second illumination light with the second surface,
wherein the first surface, the second surface, and the third surface extend horizontally in a space below the projection optical system.

35. The exposure apparatus according to 34, wherein the third surface is located below the first surface and the second surface.

36. The exposure apparatus according to claim 35, which moves the predetermined pattern and the photosensitive substrate relative to the projection optical system to project the predetermined pattern onto the photosensitive substrate to effect exposure thereof.

37. A device manufacturing method comprising:
effecting the exposure of the predetermined pattern on the photosensitive substrate, using the exposure apparatus as set forth in claim 35;
developing the photosensitive substrate on which the predetermined pattern has been transferred, to form a mask layer in a shape corresponding to the predetermined pattern on a surface of the photosensitive substrate; and
processing the surface of the photosensitive substrate through the mask layer.
